(19) United States
(12) Patent Application Publication
(10) Pub. No.: US 2024/0429308 A1
(43) Pub. Date: Dec. 26, 2024

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Wei-Chih KAO, Taipei (TW); Hsin-Che Chiang, Taipei City (TW); Chia-Lin Chiang, Changhua County (TW); Chi-Wei Wu, Hsinchu City (TW)

(73) Assignee: TAIWAN SEMICONDUCTOR MANUFACTURING COMPANY, LTD., Hsinchu (TW)

(21) Appl. No.: 18/338,161

(22) Filed: Jun. 20, 2023

(51) Int. Cl. H01L 29/66; H01L 21/8238; H01L 27/092; H01L 29/06; H01L 29/423; H01L 29/775; H01L 29/78; H01L 29/786

(52) U.S. Cl. CPC H01L 29/66795; H01L 21/823821; H01L 27/0924; H01L 29/0673; H01L 29/42392; H01L 29/66439; H01L 29/66545; H01L 29/775; H01L 29/7851; H01L 29/78696

(57) ABSTRACT

A method for forming a semiconductor structure is provided. The method includes forming a first active region and a second active region, forming a first n-type work function layer and a first p-type work function layer along the first active region and the second active region, respectively, forming a semiconductor material along the first n-type work function layer and the first p-type work function layer, removing a first portion of the semiconductor material along the first p-type work function layer, thereby leaving a second portion of the semiconductor material as a first protection layer over the first n-type work function layer, and diffusing a dopant into the first p-type work function layer to form a doped p-type work function layer while the first protection layer blocks the dopant from diffusing into the first n-type work function layer.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

As the semiconductor industry has progressed into nanometer technology process nodes in pursuit of higher device density, higher performance, and lower costs, challenges from both fabrication and design issues have resulted in the development of three-dimensional designs, such as the fin field effect transistor (FinFET). FinFETs are fabricated with a thin vertical “fin” (or active region) extending from the substrate. The channel of the FinFET is formed in this vertical fin. A gate is provided over the fin. The advantages of a FinFET may include reducing the short channel effect and providing a higher current flow.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A-1 through 2E-2 are cross-sectional views illustrating the formation of a semiconductor structure at various intermediate stages, in accordance with some embodiments of the disclosure.

FIGS. 3A-1 through 3G-2 are cross-sectional views illustrating the formation of metal gate electrode layers at various intermediate stages, in accordance with some embodiments of the disclosure.

FIG. 3G-3 is a plan view illustrating the metal gate electrode layers and neighboring components, in accordance with some embodiments of the disclosure.

FIGS. 4A, 4B and 4C illustrate the diffusion of dopants into work function layers, in accordance with some embodiments of the disclosure.

FIGS. 5A-1 through 5E-2 are cross-sectional views illustrating the formation of metal gate electrode layers at various intermediate stages, in accordance with some embodiments of the disclosure.

FIG. 5E-3 is a plan view illustrating the metal gate electrode layers and neighboring components, in accordance with some embodiments of the disclosure.

FIG. 6 is a perspective view of a semiconductor structure, in accordance with some embodiments of the disclosure.

FIGS. 7A-1 through 7E-2 are cross-sectional views illustrating the formation of a semiconductor structure at various intermediate stages, in accordance with some embodiments of the disclosure.

FIGS. 8-1 and 8-2 are cross-sectional views illustrating the metal gate electrode layers and neighboring components, in accordance with some embodiments of the disclosure.

FIG. 8-3 is a plan view illustrating the metal gate electrode layers and neighboring components, in accordance with some embodiments of the disclosure.

FIGS. 9-1 and 9-2 are a modification of the semiconductor structure of FIGS. 8-1 and 8-2, in accordance with some embodiments of the disclosure.

FIG. 9-3 is a plan view illustrating the metal gate electrode layers and neighboring components, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Embodiments of forming respective metal gate structures for various transistors (e.g., FinFET and GAA FET) with different threshold voltages in a semiconductor structure are provided. The method for forming the semiconductor structure includes doping dopants (e.g., oxygen, fluorine and/or nitrogen) into a work function layer to shift the work functions of the work function layer. The threshold voltages of the FET can be adjusted without varying the material and/or thickness of the work function layer. As a result, the transistors having different threshold voltages may be achieved on a single semiconductor substrate without degrading the gate-filling capability of the metal gate electrode layer.

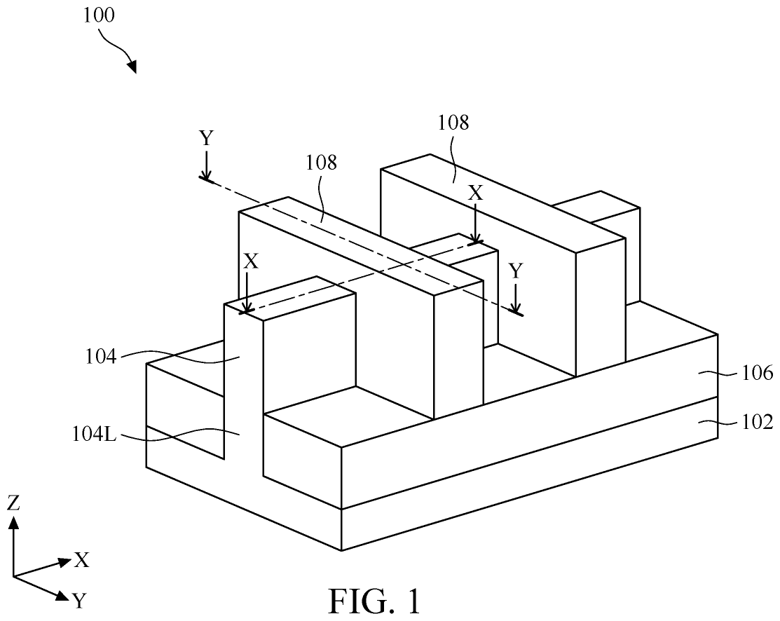

FIG. 1 is a perspective view of a semiconductor structure 100, in accordance with some embodiments of the disclosure.

The semiconductor structure 100 includes a substrate 102, and a fin structure 104 over the substrate 102, in accordance with some embodiments. The fin structure 104 is the active region of the semiconductor structure 100, in accordance with some embodiments. Although one fin structure 104 is illustrated in FIG. 1, more than one fin structure 104 may be formed over the semiconductor structure 100.

For a better understanding of the semiconductor structure, an X-Y-Z coordinate reference is provided in FIG. 1. The X-axis and Y-axis are generally orientated along the lateral directions that are parallel to the main surface of the semiconductor structure 100. The Y-axis is transverse (e.g., substantially perpendicular) to the X-axis. The Z-axis is generally oriented along the vertical direction that is perpendicular to the main surface of a semiconductor structure 100 (or the X-Y plane).

Fin structures described below may be patterned by any suitable method. For example, the fins may be patterned using one or more lithography processes, including double-patterning or multi-patterning processes. Generally, double-patterning or multi-patterning processes combine lithography and self-aligned processes, allowing patterns to be created that have, for example, pitches smaller than what is otherwise obtainable using a single, direct lithography process. For example, in one embodiment, a sacrificial layer is formed over a substrate and patterned using a lithography process. Spacers are formed alongside the patterned sacrificial layer using a self-aligned process. The sacrificial layer is then removed, and the remaining spacers may then be used to pattern the fins.

The fin structure 104 extends in the X direction, in accordance with some embodiments. That is, the fin structure 104 has a longitudinal axis parallel to the X direction, in accordance with some embodiments. The X direction may also be referred to as the channel-extending direction. The current of the resulting semiconductor devices (i.e., FinFETs) flows in the X direction through the channel. The fin structure 104 is defined as several channel regions and source/drain regions, where the channel regions and the source/drain regions are alternately arranged, in accordance with some embodiments. In this disclosure, a source/drain refers to a source and/or a drain. The number of channel regions and source/drain regions may be dependent on the demands on the design of the circuit and/or performance considerations of the semiconductor device.

An isolation structure 106 is formed over the substrate 102 and surrounds the lower portion 104L of the fin structure 104, in accordance with some embodiments. Gate structures 108 are formed with longitudinal axes parallel to the Y direction and extending across or surrounding the channel regions of the fin structure 104 and the isolation structure 106, in accordance with some embodiments. The source/drain regions of the fin structure 104 are exposed from the gate structures 108, in accordance with some embodiments. The Y direction may also be referred to as a gate-extending direction.

FIG. 1 further illustrates reference cross-sections that are used in later figures. Cross-section X-X is in a plane parallel to the longitudinal axis (X direction) and through the fin structure 104 (i.e., the active region), in accordance with some embodiments. Cross-section Y-Y is in a plane parallel to the longitudinal axis (Y direction) of the gate structure and through the gate structure or gate stack (i.e., across the channel region of the fin structure 104), in accordance with some embodiments.

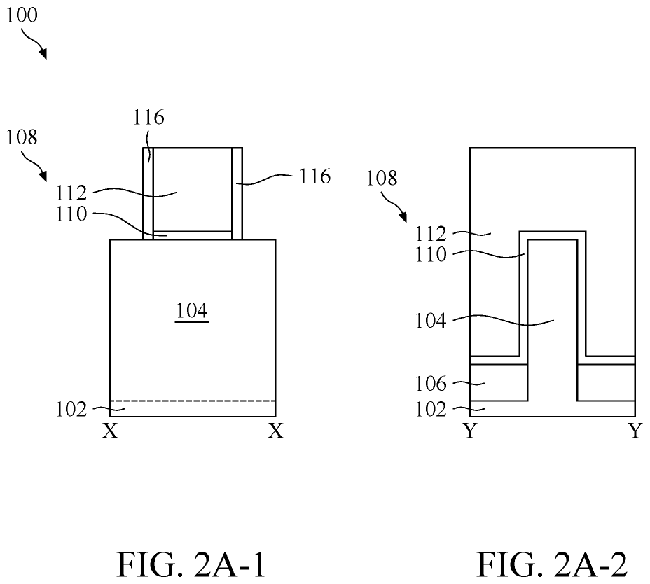

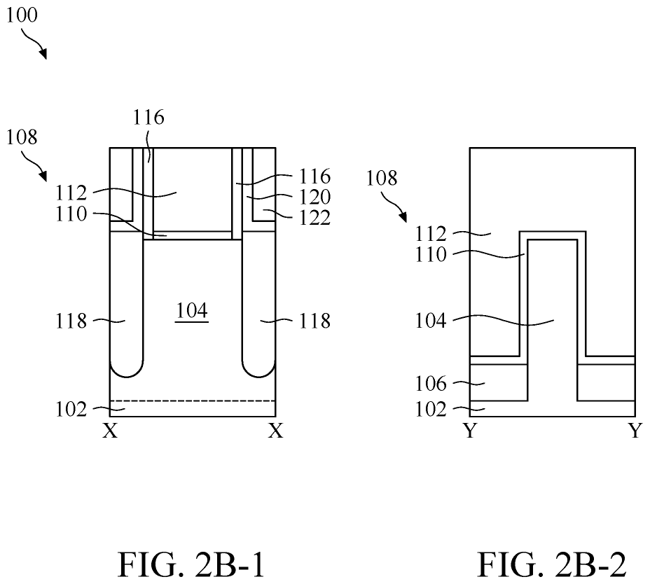

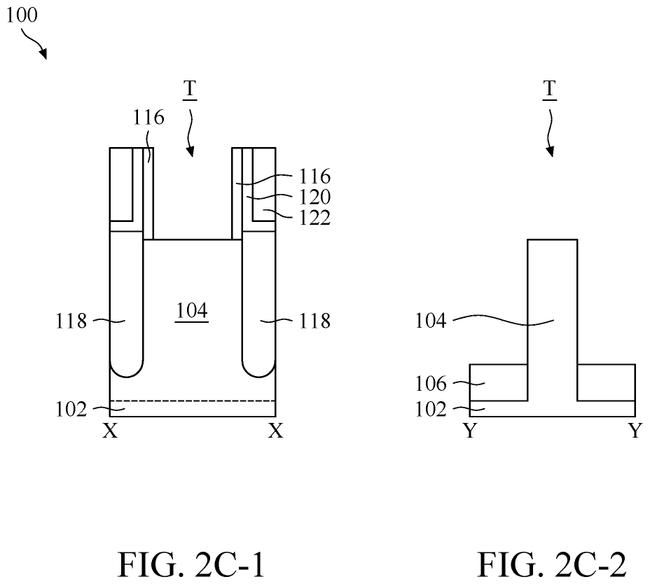

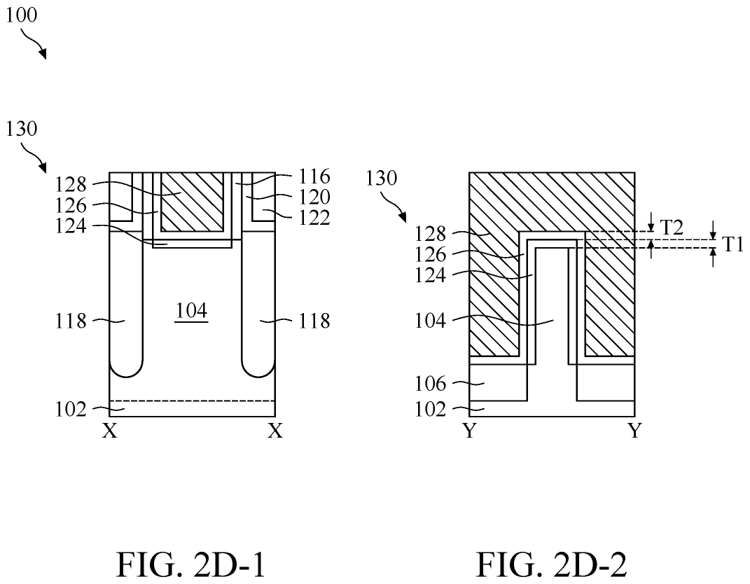

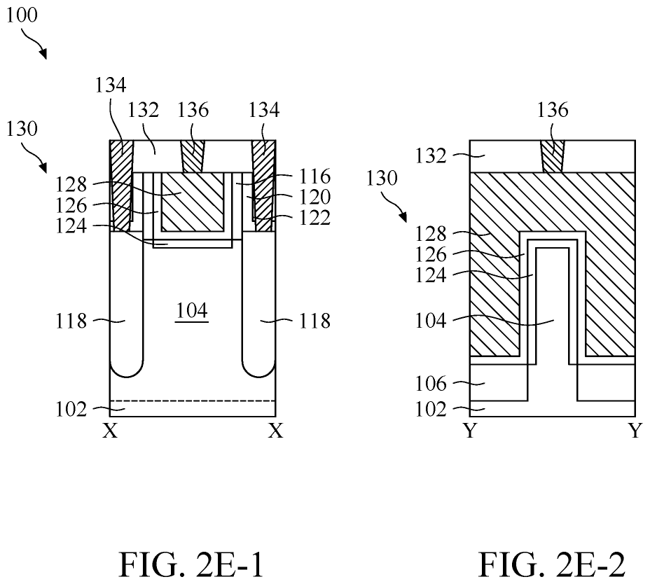

FIGS. 2A-1 through 2E-2 are cross-sectional views illustrating the formation of a semiconductor structure at various intermediate stages, in accordance with some embodiments of the disclosure. FIGS. 2A-1, 2B-1, 2C-1, 2D-1 and 2E-1 correspond to cross-section X-X of FIG. 1. FIGS. 2A-2, 2B-2, 2C-2, 2D-2 and 2E-2 correspond to cross-section Y-Y of FIG. 1.

FIGS. 2A-1 and 2A-2 illustrate a semiconductor structure 100 after the formation of an active region 104, an isolation structure 106, a gate structure 108 and gate spacer layers 116, in accordance with some embodiments.

A semiconductor structure 100 is provided, as shown in FIGS. 2A-1 and 2A-2, in accordance with some embodiments. The semiconductor structure 100 includes a substrate 102, an active region 104, an isolation structure 106, a dummy gate structure 108 and gate spacer layers 116, as shown in FIGS. 2A-1 and 2A-2, in accordance with some embodiments.

In some embodiments, the active region 104 extends in the X direction. The active region 104 has a longitudinal axis parallel to the X direction, in accordance with some embodiments. That is, the dimension (length) of the active region 104 in the X direction is greater than the dimension (width) of the active region 104 in the Y direction. In some embodiments, the active region 104 is the fin structure 104 as shown in FIG. 1.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), or indium antimonide (InSb); an alloy semiconductor such as SiGe, GaAsP, AlInAs, AlGaAs, GaInAs, GaInP, or GaInAsP; or a combination thereof. Furthermore, the substrate 102 may optionally include an epitaxial layer (epi-layer), may be strained for performance enhancement, may include a silicon-on-insulator (SOI) structure, or have other suitable enhancement features.

The formation of the active region 104 includes patterning the substrate 102 thereby forming trenches, in accordance with some embodiments. The portion of the substrate 102 that protrudes from between the trenches serves as the active region 104, in accordance with some embodiments. The patterning process may include photolithography and etching processes.

The isolation structure 106 is formed over the substrate 102 to partially fill the trenches, as shown in FIG. 2A-2, in accordance with some embodiments. The isolation structure 106 surrounds the lower portion of the active region 104, in accordance with some embodiments. The bottom surface of the isolation structure 106 is illustrated as a dash line in FIG. 2A-1. The isolation structure 106 may be also referred to as shallow trench isolation (STI) feature. In some embodiments, the isolation structure 106 is made of dielectric material such as silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof.

In some embodiments, the formation of the isolation structure 106 includes depositing a dielectric material for the isolation structure 106 to overfill the trenches. In some embodiments, the dielectric material is deposited using chemical vapor deposition (CVD) (such as such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

The dielectric material formed over the top of the active region 104 is planarized, for example, using CMP, an etching back process, or a combination thereof, in accordance with some embodiments. The dielectric material is further recessed using an etching process to expose the sidewalls of the active region 104, in accordance with some embodiments. A remainder of the dielectric material serves as the isolation structure 106, in accordance with some embodiments.

The dummy gate structure 108 extends across the channel region of the active region 104 and the isolation structure 106, as shown in FIGS. 2A-1 and 2A-2, in accordance with some embodiments. The dummy gate structure 108 surrounds the channel region of the active region 104, in accordance with some embodiments. The dummy gate structure 108 is configured as a sacrificial structure and will be replaced with a final gate stack, in accordance with some embodiments. FIG. 2A-1 shows one dummy gate structure 108 for illustrative purposes and is not intended to be limiting. The number of the dummy gate structure 108 may be dependent on the demands on the semiconductor device design and on performance considerations.

In some embodiments, the dummy gate structure 108 extends in the Y direction. The dummy gate structure 108 has longitudinal axis parallel to the Y direction, in accordance with some embodiments. That is, the dimension (length) of the dummy gate structure 108 in the Y direction are greater than the dimension (width) of the dummy gate structure 108 in the X direction.

The dummy gate structure 108 includes a dummy gate dielectric layer 110 and a dummy gate electrode layer 112 formed on the dummy gate dielectric layer 110, in accordance with some embodiments. In some embodiments, the dummy gate dielectric layer 110 is made of one or more dielectric materials, such as silicon oxide (SiO), silicon nitride (SiN), silicon oxynitride (SiON), HfO₂, HfZrO, HfSiO, HfTIO, HAIO, or a combination thereof. In some embodiments, the dielectric material is formed using thermal oxidation, CVD, ALD, physical vapor deposition (PVD), another suitable technique, or a combination thereof.

In some embodiments, the dummy gate electrode layer 112 is made of a semiconductor material such as polysilicon, poly-silicon germanium. In some embodiments, the dummy gate electrode layer 112 is made of a conductive material such as metallic nitrides, metallic silicides, metals, or a combination thereof. In some embodiments, the material for the dummy gate electrode layer 112 is formed using CVD, another suitable technique, or a combination thereof.

In some embodiments, the formation of the dummy gate structure 108 includes depositing a dielectric material for the dummy gate dielectric layer 110 over the semiconductor structure 100, depositing a material for the dummy gate electrode layer 112 over the dielectric material, planarizing the material for the dummy gate electrode layer 112, and patterning the dielectric material and the material for the dummy gate electrode layer 112 into the dummy gate structure 108.

The patterning process includes forming a patterned mask layer (such as a patterned hard mask layer or a patterned photoresist layer) over the material for the dummy gate electrode layer 112 to cover the channel region of the active region 104, in accordance with some embodiments. The materials for the dummy gate electrode layer 112 and dielectric material, uncovered by the patterned mask layer, are etched away until the source/drain regions of the active region 104 are exposed, in accordance with some embodiments.

The gate spacer layers 116 are formed along opposite sidewalls of the dummy gate structure 108, as shown in FIG. 2A-1, in accordance with some embodiments. The gate spacer layers 116 extend in the Y direction and across the active region 104 and the isolation structure 106, in accordance with some embodiments. The gate spacer layers 116 are used to offset the subsequently formed source/drain features and separate the source/drain features from the gate structure, in accordance with some embodiments.

In some embodiments, the gate spacer layers 116 are made of a dielectric material, such as silicon-containing dielectric material, such as silicon oxide (SiO₂), silicon nitride (SIN), silicon carbide (SiC), silicon oxynitride (SiON), silicon carbon nitride (SiCN), silicon oxycarbonitride (SiOCN), or oxygen-doped silicon carbonitride (Si(O)CN).

In some embodiments, the formation of the gate spacer layers 116 includes conformally depositing a dielectric material for the gate spacer layers 116 over the semiconductor structure 100 followed by an anisotropic etching process such as dry etching. The portion of the dielectric material that remains on the sidewalls of the dummy gate structure 108 serves as the gate spacer layers 116, in accordance with some embodiments.

FIGS. 2B-1 and 2B-2 illustrate a semiconductor structure 100 after the formation of source/drain features 118, a contact etching stop layer (CESL) 120 and a first interlayer dielectric (ILD) layer 122, in accordance with some embodiments.

Source/drain features 118 are formed over the source/drain regions of the active region 104, as shown in FIGS. 2B-1, in accordance with some embodiments. The source/drain features 118 are on the opposite sides of the dummy gate structure 108, in accordance with some embodiments. The formation of the source/drain features 118 includes recessing the source/drain regions of the active region 104 using the dummy gate structure 108 and the gate spacer layers 116 as a mask to form source/drain recesses on opposite sides of the dummy gate structure 108, in accordance with some embodiments. The recessing process may be an anisotropic etching process such as dry plasma etching, an isotropic etching process such as dry chemical etching, remote plasma etching, wet chemical etching, or a combination thereof.

Afterward, the source/drain features 118 are grown on the exposed surfaces of the active region 104 in the source/drain recesses using an epitaxial growth process, in accordance with some embodiments. The epitaxial growth process may be molecular beam epitaxy (MBE), metal organic chemical vapor deposition (MOCVD), or vapor phase epitaxy (VPE), or another suitable technique. In some embodiments, the source/drain features 118 are made of any suitable semiconductor material for an n-type semiconductor device and a p-type semiconductor device, such as Ge, Si, GaAs, AlGaAs, SiGe, GaAsP, SiP, SiC, SiCP, or a combination thereof.

In some embodiments, the source/drain features 118 are in-situ doped during the epitaxial growth process. For example, the n-type source/drain features for n-type semiconductor devices are doped with the n-type dopant during the epitaxial growth process. For example, the n-type dopant may be phosphorous (P) or arsenic (As). For example, the n-type source/drain features may be the epitaxially grown silicon phosphorous (SiP), silicon carbon (SiC), silicon phosphorous carbon (SiPC), silicon phosphorous arsenic (SiPAs), silicon arsenic (SiAs), silicon (Si) or a combination thereof doped with phosphorous or arsenic. In some embodiments, the concentrations of the dopant (e.g., P) in the source/drain features 118 are in a range from about 2×10¹⁹ cm⁻³ to about 3×10²¹ cm⁻³.

For example, the p-type source/drain features for p-type semiconductor devices are doped with the p-type dopant during the epitaxial growth process. For example, the p-type dopant may be boron (B) or BF₂. For example, the p-type source/drain features may be the epitaxially grown silicon germanium (SiGe), silicon germanium carbon (SiGeC), germanium (Ge), silicon (Si) or a combination thereof doped with boron (B). In some embodiments, the concentrations of the dopant (e.g., B) in the source/drain features 118 are in a range from about 1×10¹⁹ cm⁻³ to about 6×10²⁰ cm⁻³.

A contact etching stop layer 120 is formed over the semiconductor structure 100, as shown in FIG. 2B-1, in accordance with some embodiments. The contact etching stop layer 120 extends along, and covers, the surfaces of the source/drain features 118 and the sidewalls of the gate spacer layers 116, in accordance with some embodiments.

In some embodiments, the contact etching stop layer 120 is made of a dielectric material, such as silicon oxide (SiO₂), silicon nitride (SiN), silicon oxynitride (SiON), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 120 is globally and conformally deposited over the semiconductor structure 100 using CVD (such as LPCVD, PECVD, HDP-CVD, HARP, and FCVD), ALD, another suitable method, or a combination thereof.

A first interlayer dielectric layer 122 is formed over the contact etching stop layer 120, as shown in FIG. 2B-1, in accordance with some embodiments. In some embodiments, the first interlayer dielectric layer 122 is made of a dielectric material, such as silicate glass (USG), or doped silicon oxide such as borophosphosilicate glass (BPSG), fluoride-doped silicate glass (FSG), phosphosilicate glass (PSG), borosilicate glass (BSG), or another suitable dielectric material. In some embodiments, a dielectric material for the first interlayer dielectric layer 122 is deposited using such as CVD (such as HDP-CVD, PECVD, HARP or FCVD), another suitable technique, or a combination thereof.

In some embodiments, the first interlayer dielectric layer 122 is made of a different material than the contact etching stop layer 120. In some embodiments, the first interlayer dielectric layer 122 and the contact etching stop layer 120 have a great difference in etching selectivity. In some embodiments, the first interlayer dielectric layer 122 is made of an oxide (such as silicon oxide) and the contact etching stop layer 120 is made of a nitrogen-containing dielectric (such as silicon nitride or silicon oxynitride).

Afterward, the dielectric materials for the contact etching stop layer 120 and the first interlayer dielectric layer 122 above the upper surfaces of the dummy gate electrode layer 112 are removed using such as CMP until the upper surface of the dummy gate structure 108 is exposed, in accordance with some embodiments. In some embodiments, the upper surface of the first interlayer dielectric layer 122 is substantially coplanar with the upper surface of the dummy gate electrode layer 112.

FIGS. 2C-1 and 2C-2 illustrate a semiconductor structure 100 after the removal of the dummy gate structure 108, in accordance with some embodiments.

The dummy gate structure 108 is removed using an etching process to form a gate trench T, as shown in FIGS. 2C-1 and 2C-2, in accordance with some embodiments. The gate trench T exposes the channel region of the active region 104, in accordance with some embodiments. The gate trench T further exposes the sidewalls of the gate spacer layers 116 facing the channel regions, in accordance with some embodiments.

In some embodiments, the etching process includes one or more etching processes. For example, when the dummy gate electrode layer 112 is made of polysilicon, a wet etchant such as a tetramethylammonium hydroxide (TMAH) solution may be used to selectively remove the dummy gate electrode layer 112. For example, the dummy gate dielectric layer 110 may be thereafter removed using plasma dry etching, dry chemical etching, or wet etching.

FIGS. 2D-1 and 2D-2 illustrate a semiconductor structure 100 after the formation of a final gate stack 130, in accordance with some embodiments.

An interfacial layer 124 is formed on the exposed surface of the active region 104, as shown in FIGS. 2D-1 and 2D-2, in accordance with some embodiments. In some embodiments, the interfacial layer 124 is made of a chemically formed silicon oxide. In some embodiments, the interfacial layer 124 is formed using one or more cleaning processes such as including ozone (O₃), ammonia hydroxide-hydrogen peroxide-water mixture, or hydrochloric acid-hydrogen peroxide-water mixture. Semiconductor material from the active region 104 is oxidized to form the interfacial layer 124, in accordance with some embodiments. In some embodiments, the interfacial layer 124 has a thickness T1 in a range from about 5 angstrom (Å) to about 15 Å.

A gate dielectric layer 126 is formed conformally along the interfacial layer 124 to surround the active region 104 and partially fills the gate trench T, as shown in FIGS. 2E-1 and 2E-2, in accordance with some embodiments. The gate dielectric layer 126 is also conformally formed along the sidewalls of the gate spacer layers 116 facing the channel region, in accordance with some embodiments. The gate dielectric layer 126 is also conformally formed along the upper surface of the isolation structure 106, in accordance with some embodiments. In some embodiments, the gate dielectric layer 126 has a thickness T2 in a range from about 10 Å to about 20 Å.

The gate dielectric layer 126 may be high-k dielectric layer. In some embodiments, the high-k dielectric layer is a dielectric material with high dielectric constant (k value), for example, greater than 3.9. In some embodiments, the gate dielectric layer 126 is made of hafnium-containing dielectric material, such as hafnium oxide (HfO₂), HfZrO, HfSiO₄, HfZrO, HfLaO, HfSiO, HfTaO, HfTiO. In alternative embodiments, the gate dielectric layer 126 is made of TiO₂, Ta₂O₃, ZrO₂, ZrSiO₂, LaO, Al₂O₃, ZrO, TiO, Ta₂O₅, Y₂O₃, SrTiO₃ (STO), BaTiO₃ (BTO), BaZrO, LaSiO, AlSiO, (Ba,Sr)TiO₃ (BST), Si₃N₄, oxynitrides (SiON), a combination thereof, or another suitable material. The high-k dielectric layer may be deposited using ALD, PVD, CVD, or another suitable technique.

A capping layer (not shown) is conformally formed over the semiconductor structure 100, in accordance with some embodiments. The capping layer may be made of titanium nitride, silicon, titanium nitride doped with silicon (TSN), a multi-layer thereof, or a combination thereof. For example, a TSN capping layer is formed over the gate dielectric layer 126, and then an in-situ post metallization anneal (i-PMA) process is performed in accordance with some embodiments. In some embodiments, the i-PMA process is a spike anneal, which is performed at a temperature of about 850° C. to about 950° C., and in an ambient containing N₂. A silicon capping layer is formed over the TSN capping layer, and then a post cap anneal (PCA) process is performed in accordance with some embodiments. In some embodiments, the PCA process is a spike anneal, which is performed in an ambient containing N₂ and at a temperature in a range from about 900° C. to about 950° C.

The TSN capping layer and the silicon capping layer are removed using one or more etching processes until the gate dielectric layer 126 is exposed, in accordance with some embodiments. The etching processes may be an anisotropic etching process such as dry plasma etching, an isotropic etching process such as dry chemical etching, remote plasma etching, wet chemical etching, or a combination thereof. Afterward, a post deposition anneal (PDA) process is performed on the gate dielectric layer 126, in accordance with some embodiments. In some embodiments, the PDA process is a spike anneal, which is performed at a temperature of about 850° C. to about 950° C., and in an ambient containing NH₃.

The capping layers and these anneal processes may be helpful in improving the crystallization of the gate dielectric layer 126 and reducing the defects in the gate dielectric layer 126, which may improve the quality of the gate dielectric layer 126, e.g., thereby enhancing the performance of semiconductor devices.

A metal gate electrode layer 128 is formed over the gate dielectric layer 126 to overfill a remainder of the gate trench T, as shown in FIGS. 2D-1 and 2D-2, in accordance with some embodiments. The metal gate electrode layer 128 is nested within the gate dielectric layer 126, in accordance with some embodiments. The interfacial layer 124, the gate dielectric layer 126 and the metal gate electrode layer 128 combine to form a final gate stack 130, as shown in FIGS. 2D-1 and 2D-2, in accordance with some embodiments.

In some embodiments, the metal gate electrode layer 128 is made of more than one conductive material, such as a metal, metal alloy, conductive metal oxide or metal nitride, another suitable conductive material, or a combination thereof. As discussed in detail below, the metal gate electrode layer 128 may be a multi-layer structure with various combinations of a work function layer with a selected work function to enhance the device performance for n-type transistors and p-type transistors, a protection layer, a gate metal fill layer, or another suitable layer.

A planarization process such as CMP is performed on the semiconductor structure 100 to remove the final gate stack 130 formed over the upper surface of the first interlayer dielectric layer 122, in accordance with some embodiments. After the planarization process, the upper surface of the metal gate electrode layer 128 is substantially coplanar with the upper surface of the first interlayer dielectric layer 122, in accordance with some embodiments.

In some embodiments, the final gate stack 130 extends in the Y direction. The final gate stack 130 has a longitudinal axis parallel to the Y direction, in accordance with some embodiments. That is, the dimension (length) of the final gate stack 130 in the Y direction is greater than the dimension (width) of the final gate stack 130 in the X direction, in accordance with some embodiments.

The final gate stack 130 surrounds the channel region of the active region 104 and are interposed between the source/drain features 118, in accordance with some embodiments. The final gate stack 130 combines with the source/drain features 118 and the channel region of the active region 104 to form a FinFET device, such as an n-channel FinFET device or a p-channel FinFET device, in accordance with some embodiments. The final gate stack 130 may engage the channel region of the active region 104, so that current can flow between the source/drain features 118 during operation.

FIGS. 2E-1 and 2E-2 illustrate a semiconductor structure 100 after the formation of a second interlayer dielectric layer 132, contact plugs 134 and a via 136, in accordance with some embodiments.

A second interlayer dielectric layer 132 is formed over the semiconductor structure 100, as shown in FIGS. 2E-1 and 2E-2, in accordance with some embodiments. In some embodiments, the second interlayer dielectric layer 132 is made of dielectric material, such as USG, BPSG, FSG, PSG, BSG, or another suitable dielectric material. In some embodiments, the second interlayer dielectric layer 132 is deposited using such as CVD (such as HDP-CVD, PECVD, HARP or FCVD), another suitable technique, or a combination thereof.

Contact plugs 134 are formed in or through the second interlayer dielectric layer 132, the first interlayer dielectric layer 122 and the contact etching stop layer 120 and land on the source/drain features 118, as shown in FIG. 2E-1, in accordance with some embodiments. The contact plugs 134 are electrically connected to the source/drain features 118, in accordance with some embodiments.

In some embodiments, the formation of the contact plugs 134 includes patterning the second interlayer dielectric layer 132, the first interlayer dielectric layer 122 and the contact etching stop layer 120 to form contact openings (where the contact plugs 134 are to be formed) using photolithography and etching processes until the source/drain features 118 are exposed. Silicide layers (not shown) are formed on the exposed surfaces of the source/drain features 118. In some embodiments, the silicide layers are made of WSi, NiSi, TiSi or CoSi.

Afterward, one or more conductive materials for the contact plugs 134 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 132 are planarized using, for example, CMP. After the planarization process, the upper surfaces of the contact plugs 134 and the upper surface of the second interlayer dielectric layer 132 are substantially coplanar, in accordance with some embodiments.

The contact plugs 134 may have a multilayer structure including, for example, liner layers, glue layers, barrier layers, seed layers, metal bulk layers, another suitable layer, or a combination thereof. For example, a barrier/adhesive layer (not shown) may optionally be deposited along the sidewalls and the bottom surfaces of the contact openings. A metal bulk layer is then deposited on the barrier/adhesive layer (if formed) to fill the remainder of the contact openings 150.

The barrier/adhesive layer is used to prevent the metal in the subsequently formed metal material from diffusing into the dielectric material, and to improve adhesion between the subsequently formed metal bulk material and the dielectric materials. The barrier/adhesive layer may be made of tantalum (Ta), tantalum nitride (TaN), titanium (Ti), titanium nitride (TiN), cobalt tungsten (CoW), another suitable material, or a combination thereof. If the subsequently formed metal material does not easily diffuse into the dielectric material, the barrier layer may be omitted.

In some embodiments, the metal bulk layer is formed using a selective deposition technique such as cyclic CVD process or ELD process, and it is not necessary to form an adhesive layer in the contact openings before depositing the metal bulk material. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

A via 136 is formed in and/or through the second interlayer dielectric layer 132 and land on the metal gate electrode layer 128 of the final gate stack 130, as shown in FIGS. 2E-1 and 2E-2, in accordance with some embodiments. The via 136 is electrically connected to the metal gate electrode layer 128 of the final gate stack 130 and may be also referred to as gate via (VG), in accordance with some embodiments.

In some embodiments, the formation of the via 136 includes patterning the second interlayer dielectric layer 132 to form a via opening (where the via 136 are to be formed) using photolithography and etching processes. In some embodiments, the final gate stack 130 is exposed from the via opening for the via 136.

Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 132 are planarized using, for example, CMP. After the planarization process, the upper surface of the via 136, the upper surfaces of the contact plugs 134, and the upper surface of the second interlayer dielectric layer 132 are substantially coplanar, in accordance with some embodiments.

The via 136 may have a multilayer structure. For example, a barrier/adhesive layer (not shown) may optionally be deposited along the sidewalls and the bottom surfaces of the via opening. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the via opening. In some embodiments, the metal bulk layers are made of one or more conductive materials, such as cobalt (Co), nickel (Ni), tungsten (W), titanium (Ti), tantalum (Ta), copper (Cu), aluminum (Al), ruthenium (Ru), molybdenum (Mo), another suitable metal material, or a combination thereof.

It is understood that the semiconductor structure 100 may undergo further CMOS processes to form various features over the semiconductor structure 100, such as a multilayer interconnect structure (e.g., metal lines, inter metal dielectric layers, passivation layers, etc.)

Although FIGS. 2E-1 and 2E-2 only show one transistor of the semiconductor structure 100, the semiconductor structure 100 may include various types of transistors having different threshold voltages (Vt). Threshold voltages are the required gate voltages to turn on field effect transistors. For example, three different threshold voltages (e.g., standard, low and ultra-low voltages) are set for n-channel transistors, and three different threshold voltages (e.g., standard, low and ultra-low voltages) are set for p-channel transistors. These transistors may be formed in different device regions such as a logic region, a memory region, an analog region, a peripheral region, or a combination thereof, and formed with different gate electrode materials, in accordance with some embodiments.

The threshold voltage may depend on the semiconductor material of the FET channel region and/or the effective work function (EWF) value of a gate stack of the FET. For example, for an n-type FET, reducing the difference between the EWF value(s) of the NFET gate stack and the conduction band energy of the material (e.g., 4.1 eV for Si or 3.8 eV for SiGe) of the NFET channel region can reduce the NFET threshold voltage. For a p-type FET (PFET), reducing the difference between the EWF value(s) of the PFET gate stack and the valence band energy of the material (e.g., 5.2 eV for Si or 4.8 eV for SiGe) of the PFET channel region can reduce the PFET threshold voltage. The EWF values of the FET gate structures may depend on the thickness and/or material composition of each of the layers of the gate stack. Accordingly, FETs can be manufactured with different threshold voltages by adjusting the thickness and/or material composition of the FET gate stacks.

As used herein, the term “n-type work function metal (nWFM)” defines a metal or a metal-containing material with a work function that is closer to a conduction band energy than a valence band energy of semiconductor material of a FET channel region. In some embodiments, the term “n-type work function metal (nWFM)” defines a metal or a metal-containing material with a work function of less than 4.5 eV.

As used herein, the term “p-type work function metal (pWFM)” defines a metal or a metal-containing material with a work function that is closer to a valence band energy than a conduction band energy of a semiconductor material of a FET channel region. In some embodiments, the term “p-type work function metal (pWFM)” defines a metal or a metal-containing material with a work function that is equal to or greater than 4.5 eV.

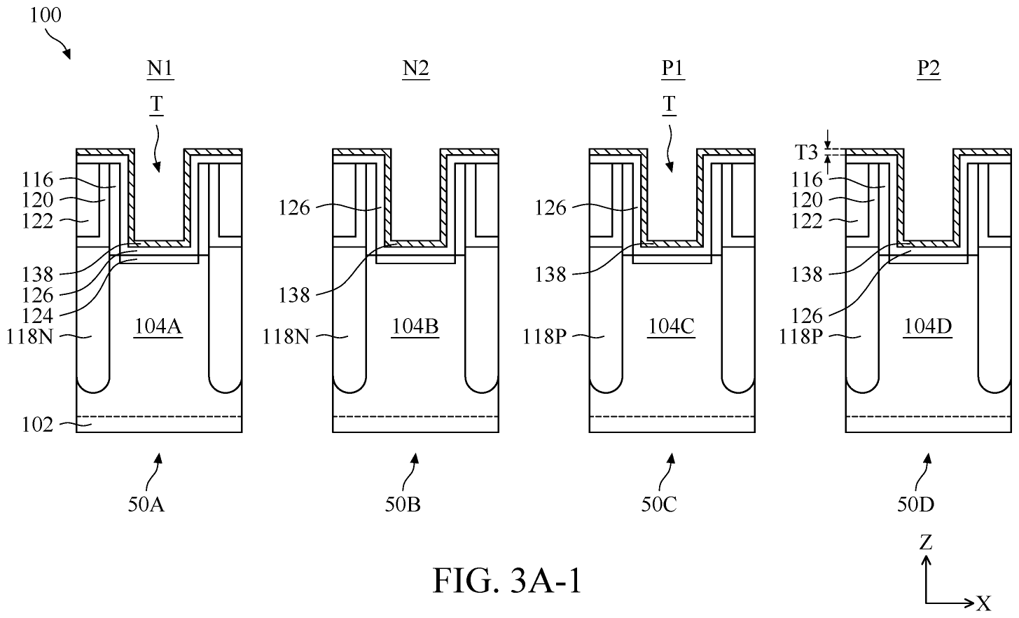

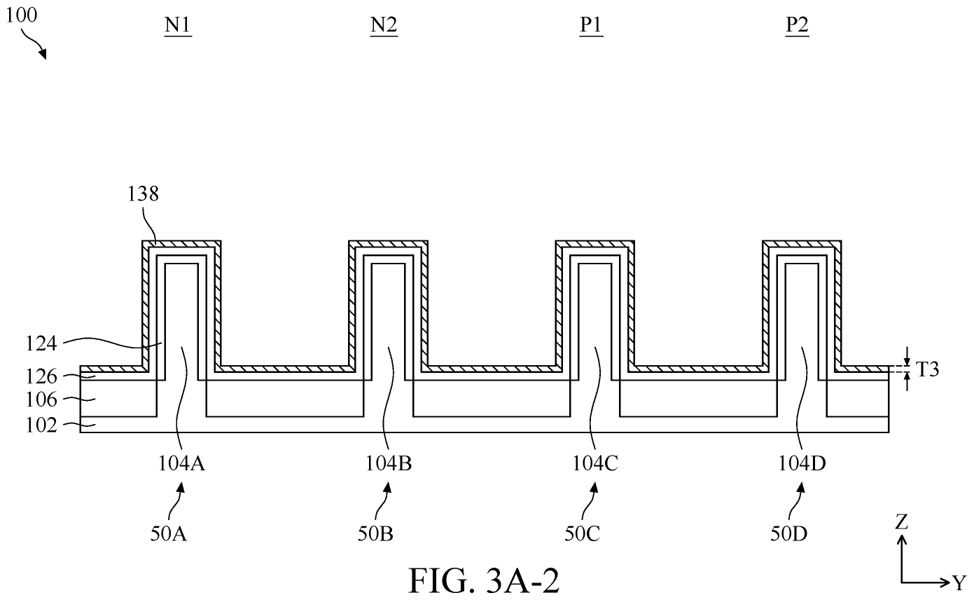

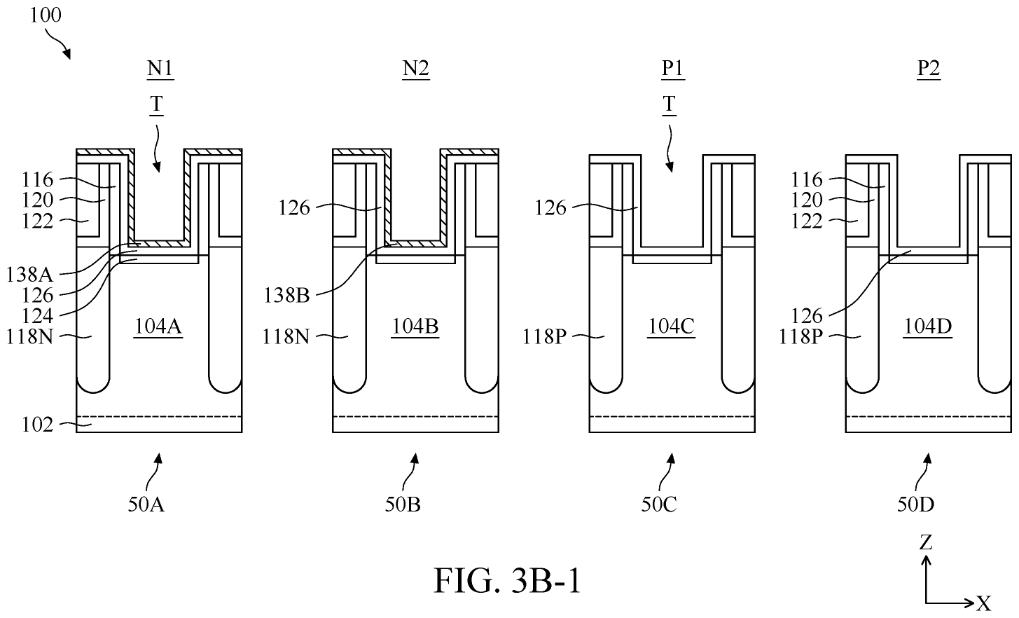

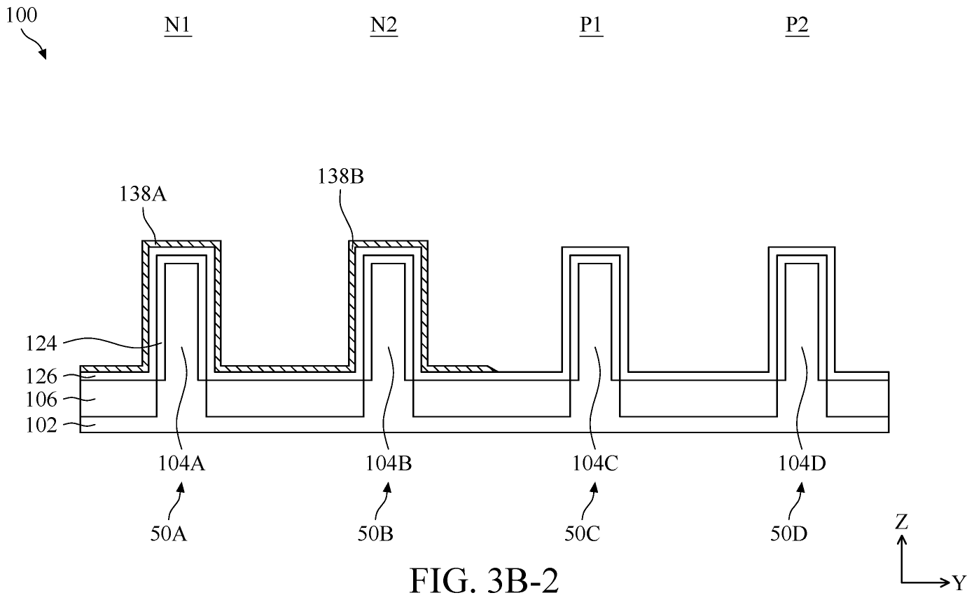

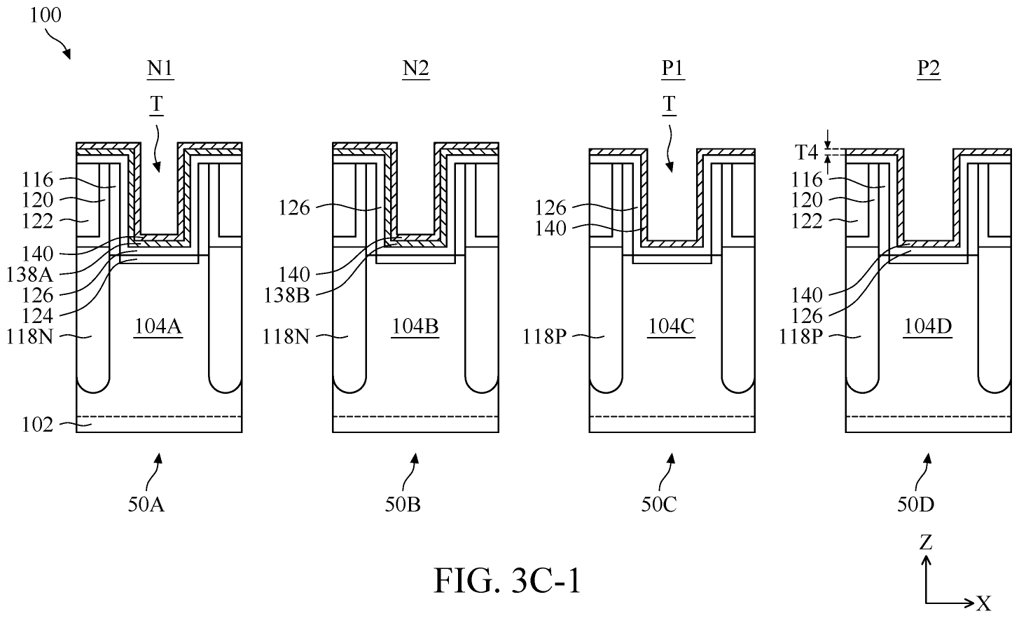

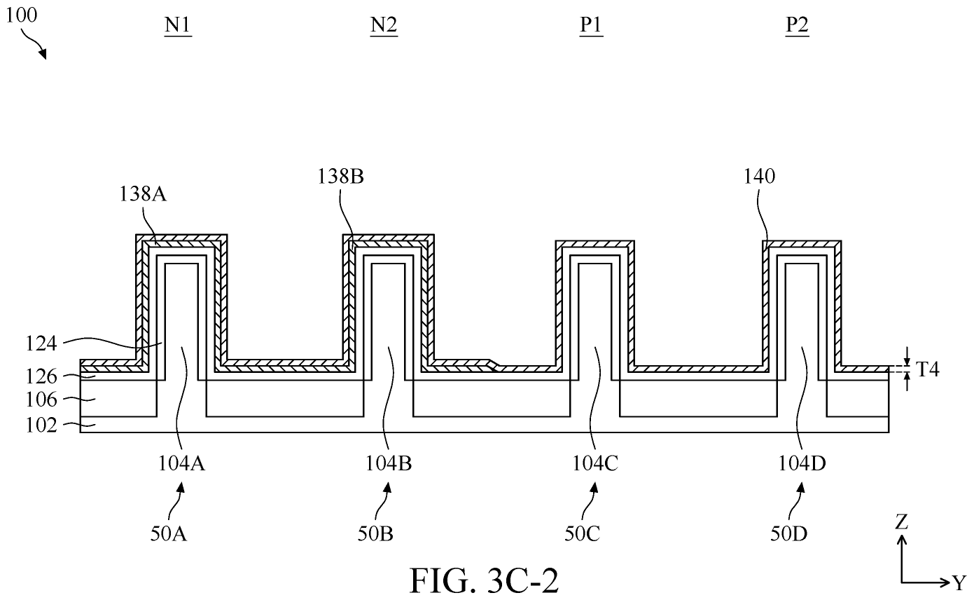

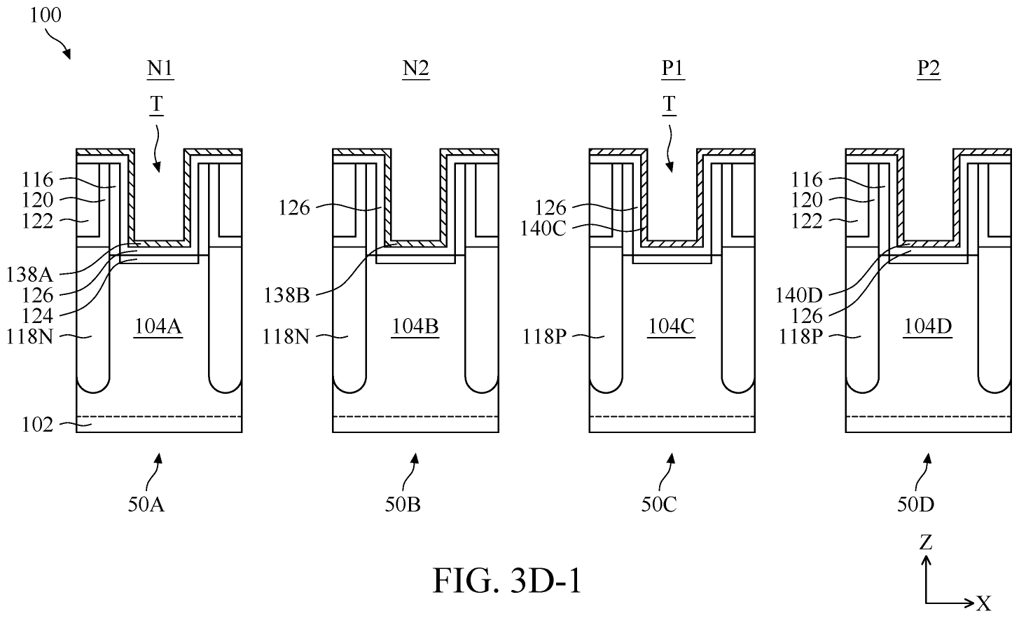

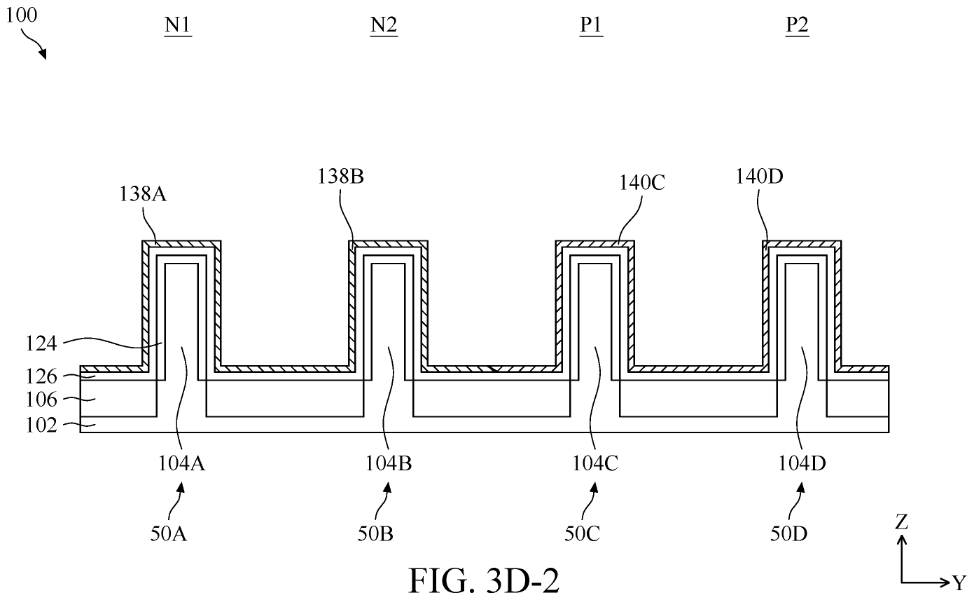

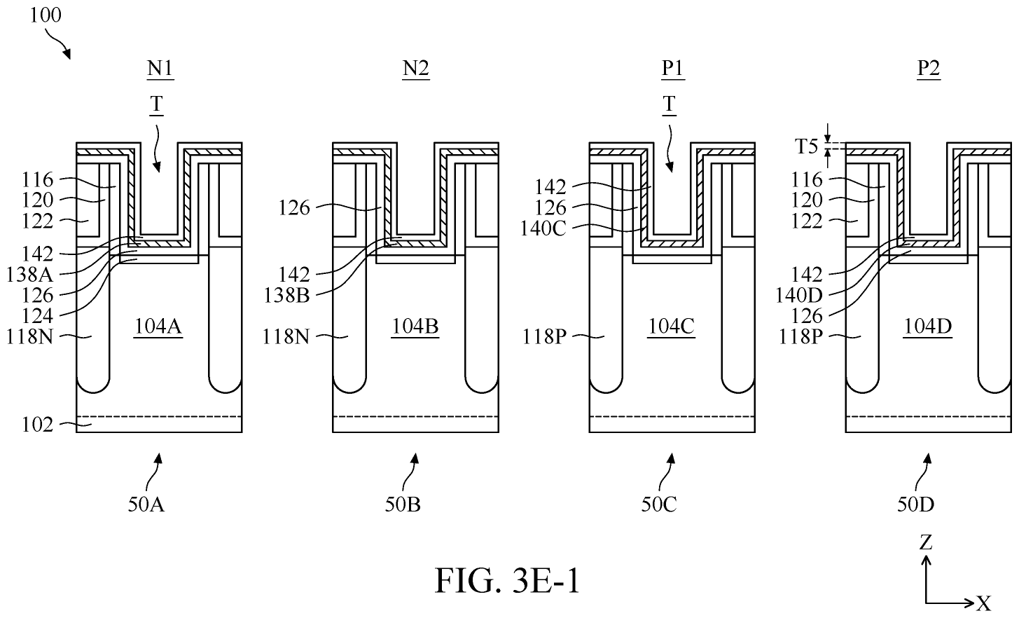

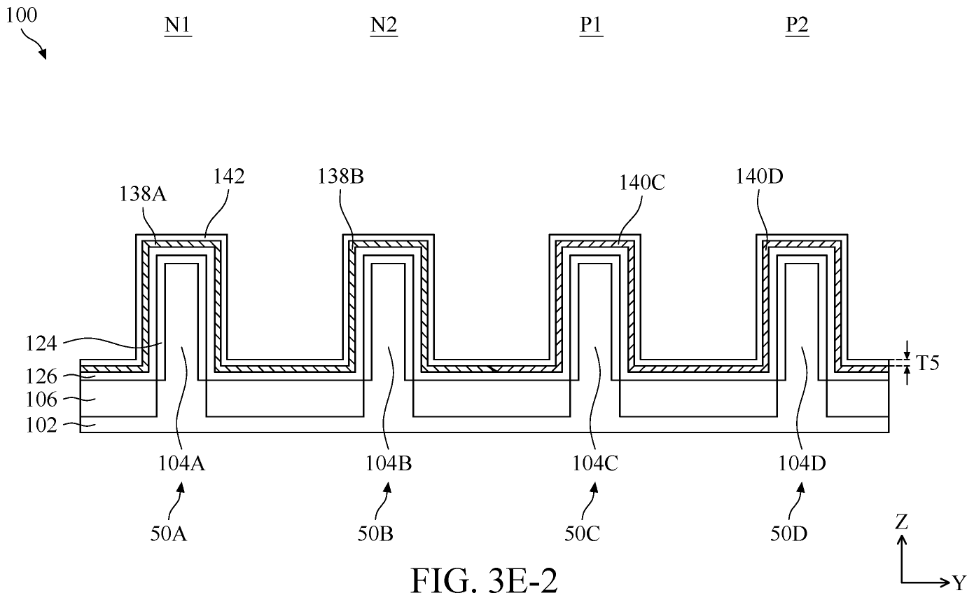

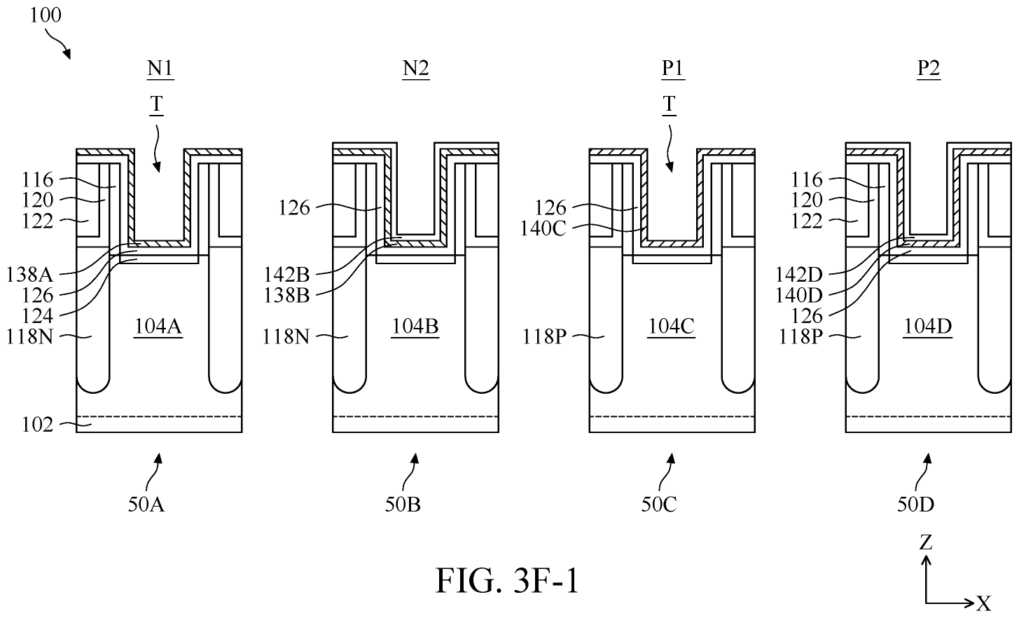

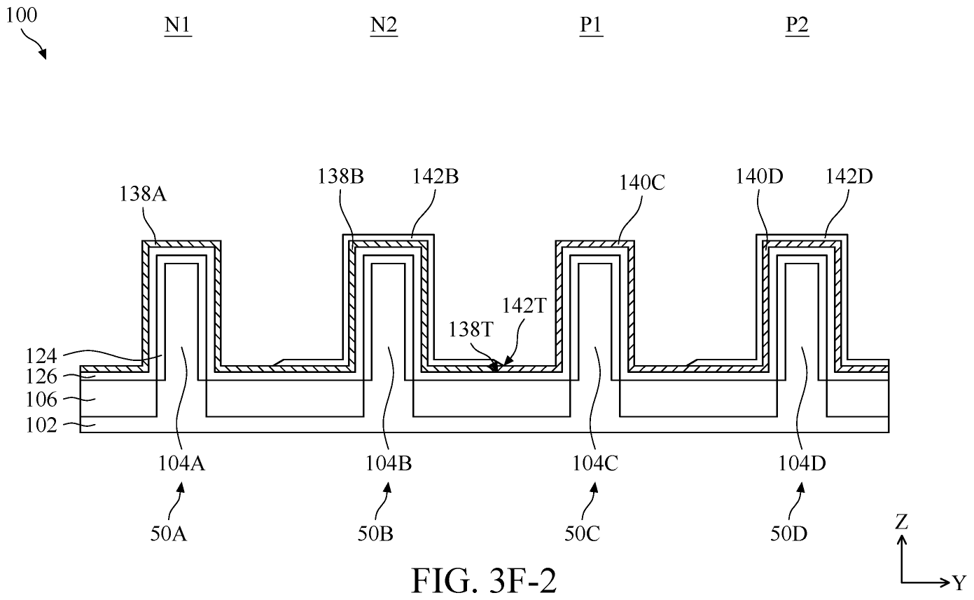

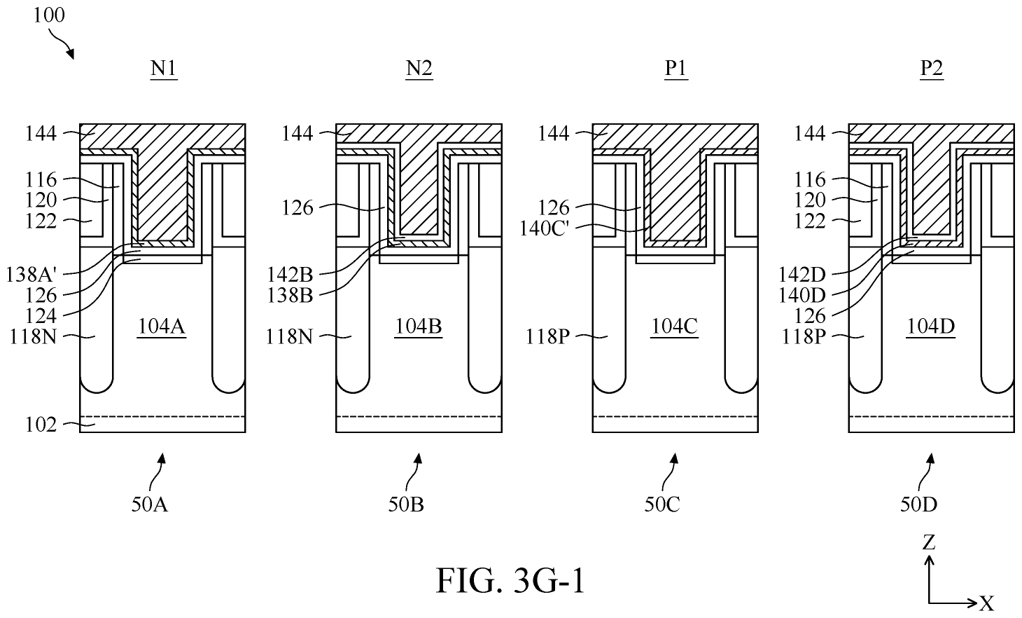

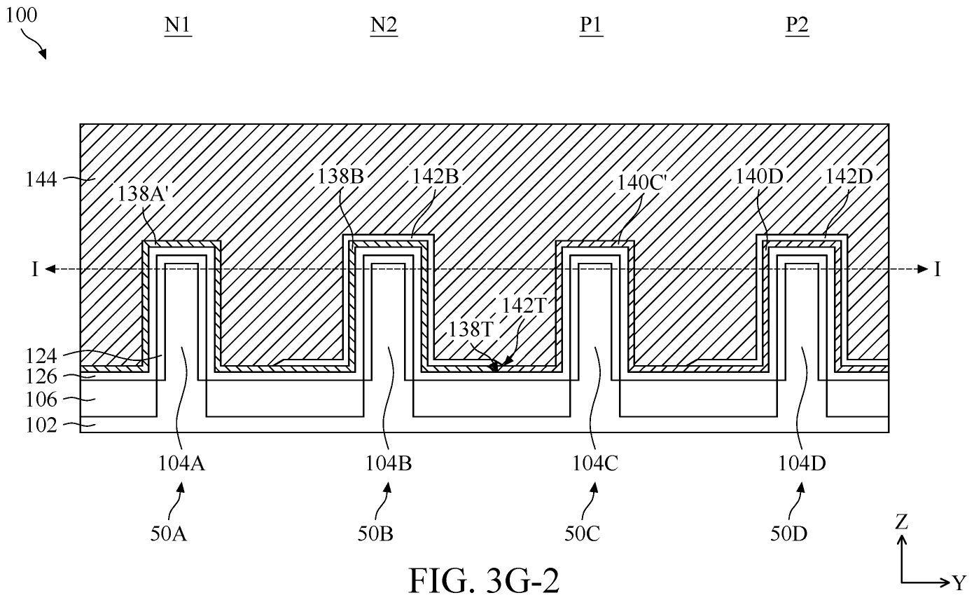

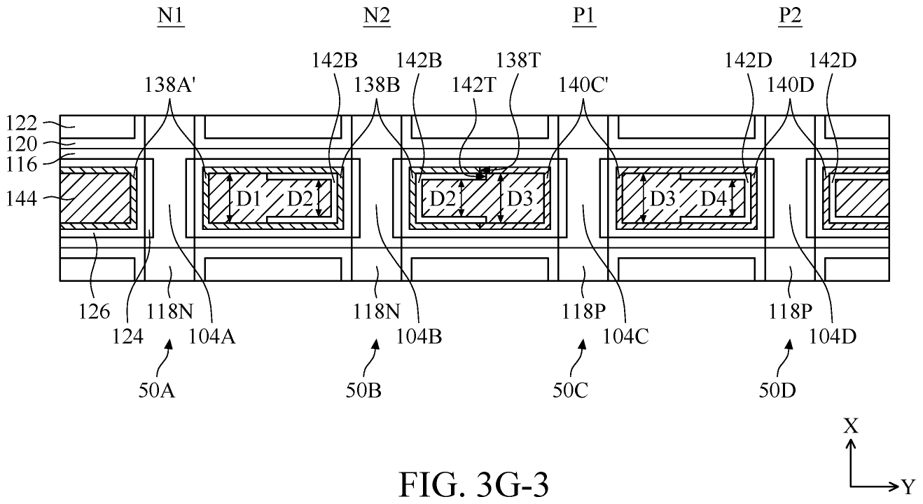

FIGS. 3A-1 through 3G-2 are cross-sectional views illustrating the formation of the metal gate electrode layers 128 (shown in FIGS. 2E-1 and 2E-2) for various types of transistors having different threshold voltages at various intermediate stages, in accordance with some embodiments of the disclosure. FIGS. 3A-1, 3B-1, 3C-1, 3D-1, 3E-1, 3F-1 and 3G-1 correspond to cross-section X-X of FIG. 1. FIGS. 3A-2, 3B-2, 3C-2, 3D-2, 3E-2, 3F-2 and 3G-2 correspond to cross-section Y-Y of FIG. 1.

FIGS. 3A-1 and 3A-2 illustrate the semiconductor structure after the formation of a work function layer 138, in accordance with some embodiments.

The substrate 102 includes device regions 50A, 50B, 50C and 50D, as shown in FIGS. 3A-1 and 3A-2, in accordance with some embodiments. The active regions formed in the device regions 50A, 50B, 50C and 50D are denoted as active regions 104A, 104B, 104C and 104D, respectively, in accordance with some embodiments. In some embodiments, an n-type transistor N1 is predetermined to be formed on the active region 104A in the device region 50A and has a threshold voltage Vn1 (e.g., standard voltage). In some embodiments, an n-type transistor N2 is predetermined to be formed on the active region 104B in the device region 50B and has a threshold voltage Vn2 (e.g., low voltage or ultra-low voltage). Here, 0<Vn2<Vn1.

In some embodiments, a p-type transistor P1 is predetermined to be formed on the active region 104C in the device region 50C and has a threshold voltage Vp1 (e.g., low voltage or ultra-low voltage). In some embodiments, a p-type transistor P2 is predetermined to be formed on the active region 104D in the device region 50D and has a threshold voltage Vp2 (e.g., standard voltage). Here, Vp2<Vp1<0.

In some embodiments, the n-type transistors N1 and N2 are n-channel FinFETs, and the p-type transistors P1 and P2 are p-channel FinFETs. The source/drain features 118 formed in the device regions 50A and 50B are n-type source/drain features and denoted as source/drain features 118N, and the source/drain features 118 formed in the device regions 50C and 50D are p-type source/drain features and denoted as source/drain features 118P, in accordance with some embodiments.

After the PDA process described above in FIGS. 2D-1 and 2D-2, a work function layer 138 is formed over the semiconductor structure 100 at the device regions 50A, 50B, 50C and 50D, as shown in FIGS. 3A-1 and 3A-2, in accordance with some embodiments. The work function layer 138 is formed on the gate dielectric layer 126 and partially fills the gate trench T, in accordance with some embodiments.

In some embodiments, the work function layer 138 is n-type work function metal, e.g., Ti, Ag, Al, TiAl, TiAlN, TiAlC, TaAl, TaC, TaCN, TaSIN, TaAlC, Mn, Zr, another suitable n-type work function metal, or a combination thereof. The material of the work function layer 138 is selected to assist in providing a desired work function for the n-type transistor N2. The work function layer 138 is deposited using ALD, CVD, PVD, another suitable technique, or a combination thereof. In some embodiments, the work function layer 138 has a thickness T3 in a range from about 10.0 Å to about 50.0 Å.

FIGS. 3B-1 and 3B-2 illustrate the semiconductor structure after a patterning process, in accordance with some embodiments.

A patterning process is performed on the work function layer 138, as shown in FIGS. 3B-1 and 3B-2, in accordance with some embodiments. The patterning process includes forming a mask layer (not shown) over the work function layer 138 at the device regions 50A and 50B, in accordance with some embodiments. The mask layer exposes the work function layer 138 at the device regions 50C and 50D, in accordance with some embodiments. In some embodiments, the mask layer is a patterned photoresist layer. For example, a photoresist may be formed over the work function layer 138 such as by using spin-on coating, and patterned by exposing the photoresist to light using an appropriate photomask. Exposed or unexposed portions of the photoresist may be removed depending on whether a positive or negative resist is used.

In alternative embodiments, the mask layer is a patterned hard mask layer which is made of a material having a different etching selectivity from the work function layer 138. The mask layer may be made of metal oxide (e.g., AlO, TiO, LaO, HfO, etc.), a nitrogen-free anti-reflection layer (NFARL), carbon-doped silicon dioxide (e.g., SiO₂:C), titanium nitride (TiN), boron nitride (BN), a multilayer thereof, another suitable material, or a combination thereof. For example, a material for the mask layer is deposited over the work function layer 138. A patterned photoresist layer may be formed over the material for the mask layer using the photolithography process described above. The material for the mask layer may be etched using the patterned photoresist layer to form the mask layer.

The patterning process also includes performing an etching process using the mask layer to remove the portion of the work function layer 138 at the device regions 50C and 50D until the gate dielectric layer 126 is exposed, in accordance with some embodiments. The remaining portions of the work function layer 138 at the device regions 50A and 50B are denoted as work function layer 138A and 138B. The etching process may be an anisotropic etching process such as dry plasma etching, an isotropic etching process such as dry chemical etching, remote plasma etching, wet chemical etching, or a combination thereof. In some embodiments, the mask layer is removed in the etching process or by an additional etching process or ashing process.

FIGS. 3C-1 and 3C-2 illustrate the semiconductor structure after the formation of a work function layer 140, in accordance with some embodiments.

A work function layer 140 is formed over the semiconductor structure 100 at the device regions 50A, 50B, 50C and 50D, as shown in FIGS. 3C-1 and 3C-2, in accordance with some embodiments. At the device regions 50A and 50B, the work function layer 140 is formed on the work function layers 138A and 138B and partially fills the gate trench T, in accordance with some embodiments. At the device regions 50C and 50D, the work function layer 140 is formed on the gate dielectric layer 126 and partially fills the gate trench T, in accordance with some embodiments.

In some embodiments, the work function layer 140 is p-type work function metal, e.g., TIN, WN, WCN, TaN, Ru, Co, W, another suitable p-type work function metal, or a combination thereof. The material of the work function layer 140 is selected to assist in providing a desired work function for the p-type transistor P2. The work function layer 140 is deposited using ALD, CVD, PVD, another suitable technique, or a combination thereof. In some embodiments, the work function layer 140 has a thickness T4 in a range from about 10.0 Å to about 50.0 Å.

FIGS. 3D-1 and 3D-2 illustrate the semiconductor structure after a patterning process, in accordance with some embodiments.

A patterning process is performed on the work function layer 140, as shown in FIGS. 3D-1 and 3D-2, in accordance with some embodiments. The patterning process includes forming a mask layer (not shown) over the work function layer 140 at the device regions 50C and 50D, in accordance with some embodiments. The mask layer exposes the work function layer 140 at the device regions 50A and 50B, in accordance with some embodiments. In some embodiments, the mask layer is a patterned photoresist layer or a patterned hard mask layer. The formation of the mask layer may the same as the mask layer discussed above in FIGS. 3B-1 and 3B-2.

The patterning process also includes performing an etching process using the mask layer to remove the portion of the work function layer 140 at the device regions 50A and 50B until the work function layers 138A and 138B are exposed, in accordance with some embodiments. The remaining portions of the work function layer 140 at the device regions 50C and 50D are denoted as work function layers 140C and 140D. The etching process may be an anisotropic etching process such as dry plasma etching, an isotropic etching process such as dry chemical etching, remote plasma etching, wet chemical etching, or a combination thereof. In some embodiments, the mask layer is removed in the etching process or by an additional etching process or ashing process. In some embodiments, a terminus the work function layer 138B is interfaced with a terminus the work function layer 140C, as shown in FIG. 3D-2.

FIGS. 3E-1 and 3E-2 illustrate the semiconductor structure after the formation of a protection layer 142, in accordance with some embodiments.

A protection layer 142 is formed over the semiconductor structure 100 at the device regions 50A, 50B, 50C and 50D, as shown in FIGS. 3E-1 and 3E-2, in accordance with some embodiments. At the device regions 50A and 50B, the protection layer 142 is formed on the work function layers 138A and 138B and partially fills gate trench T, in accordance with some embodiments. At the device regions 50C and 50D, the protection layer 142 is formed on the work function layers 140C and 140D and partially fills the gate trench T, in accordance with some embodiments.

In some embodiments, the protection layer 142 is made of semiconductor material such as silicon. In alternative embodiments, the protection layer 142 is made of metal material such as titanium, metal nitride such as TiN or TSN (titanium nitride doped with silicon), or a combination thereof. The protection layer 142 is configured to block impurities and dopants (e.g., oxygen, fluorine, nitrogen, etc.) from diffusing into the work function layers 138 and 140, in accordance with some embodiments. The protection layer 142 is deposited using ALD, CVD, PVD, another suitable technique, or a combination thereof.

In some embodiments, the protection layer 142 has a thickness T5 in a range from about 10.0 Å to about 30.0 Å. In some embodiments, the thickness T5 of the protection layer 142 is less than the thickness T3 of the work function layer 138 and the thickness T4 of the work function layer 140. In some embodiments, the ratio (T5/T3 or T5/T4) of the thickness T4 to the thickness T2 or the thickness T4 to the thickness T3 is in a range from about 0.3 to about 0.9. If the thickness T5 or the ratio (T5/T3) is too small, the protection layer 142 may not sufficiently block the diffusion of the impurities and dopants. If the thickness T5 or the ratio (T5/T3) is too great, the resistance of the resulting gate electrode layer may increase.

FIGS. 3F-1 and 3F-2 illustrate the semiconductor structure after a patterning process, in accordance with some embodiments.

A patterning process is performed on the protection layer 142, as shown in FIGS. 3F-1 and 3F-2, in accordance with some embodiments. The patterning process includes forming a mask layer (not shown) over the protection layer 142 at the device regions 50B and 50D, in accordance with some embodiments. The mask layer the exposes the protection layer 142 at the device regions 50A and 50C, in accordance with some embodiments. In some embodiments, the mask layer is a patterned photoresist layer or a patterned hard mask layer. The formation of the mask layer may be similar to the mask layer discussed above in FIGS. 3B-1 and 3B-2.

The patterning process also includes performing an etching process using the mask layer to remove the portion of the protection layer 142 at the device regions 50A and 50C until the work function layer 138A and the work function layer 140C are exposed, in accordance with some embodiments. The remaining portions of the protection layer 142 at the device regions 50B and 50D are denoted as protection layers 142B and 142D. The etching process may be an anisotropic etching process such as dry plasma etching, an isotropic etching process such as dry chemical etching, remote plasma etching, wet chemical etching, or a combination thereof. In some embodiments, the mask layer is removed in the etching process or by an additional etching process or ashing process.

The protection layer 142B extends over and protects the work function layer 138B, and the protection layer 142D extends over and protects the work function layer 140D, in accordance with some embodiments. In some embodiments, the protection layer 142B extends beyond the terminus 138T of the work function layer 138B, as shown in FIG. 3F-2. In some embodiments, the terminus 142T of the protection layer 142B is located closer to the sidewall of the active region 104C than the terminus 138T of the work function layer 138B.

FIGS. 3G-1 and 3G-2 illustrate the semiconductor structure after the formation of a gate metal fill layer 144, in accordance with some embodiments.

A gate metal fill layer 144 is formed over the semiconductor structure 100 at the device regions 50A, 50B, 50C and 50D to overfill the remainder of the gate trench T, as shown in FIGS. 3G-1 and 3G-2, in accordance with some embodiments. At the device region 50A, the gate metal fill layer 144 is formed on the work function layer 138A, in accordance with some embodiments. At the device region 50B, the gate metal fill layer 144 is formed on the protection layer 142B, in accordance with some embodiments. At the device region 50C, the gate metal fill layer 144 is formed on the work function layer 140C, in accordance with some embodiments. At the device region 50D, the gate metal fill layer 144 is formed on the protection layer 142D, in accordance with some embodiments.

It should be noted that the work function layer 138A and the work function layer 140C, uncovered by the protection layer 142, may be doped with dopants and/or impurities during some thermal processes (e.g., the deposition process for forming the gate metal fill layer 144). The doped work function layer 138A and the work function layer 140C are respectively denoted as 138A′ and 140C′, as shown in FIGS. 3G-1 and 3G-2. This will be discussed in detail later.

In some embodiments, the gate metal fill layer 144 is made of metal material with lower resistance, for example, tungsten (W), titanium (Ti), silver (Ag), ruthenium (Ru), molybdenum (Mo), copper (Cu), cobalt (Co), Al, iridium (Ir), nickel (Ni), metal alloys, and a combination thereof. In some embodiments, the gate metal fill layer 144 is formed using ALD, CVD, PVD, electroplating process, another suitable technique, or a combination thereof. In some embodiments, the gate metal fill layer 144 has a thickness in a range from about 100 Å to about 1000 Å.

In some embodiments, the work function layer 138A′ and the gate metal fill layer 144 combine to form the metal gate electrode layer of the n-type transistor N1. In some embodiments, the work function layer 138B, the protection layer 142B and the gate metal fill layer 144 combine to form the metal gate electrode layer of the n-type transistor N2. In some embodiments, the work function layer 140C′ and the gate metal fill layer 144 combine to form the metal gate electrode layer of the p-type transistor P1. In some embodiments, the work function layer 140D, the protection layer 142D, and the gate metal fill layer 144 combine to form the metal gate electrode layer of the p-type transistor P2.

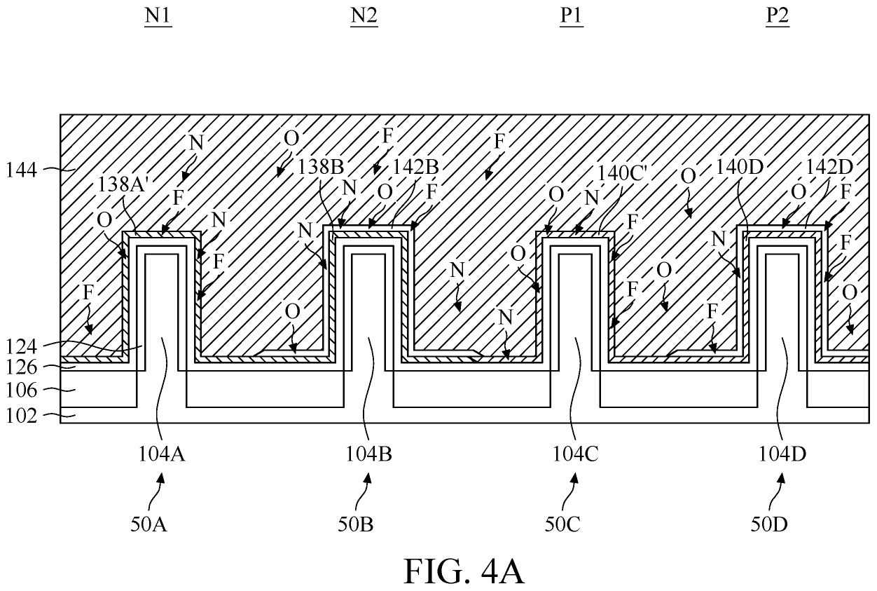

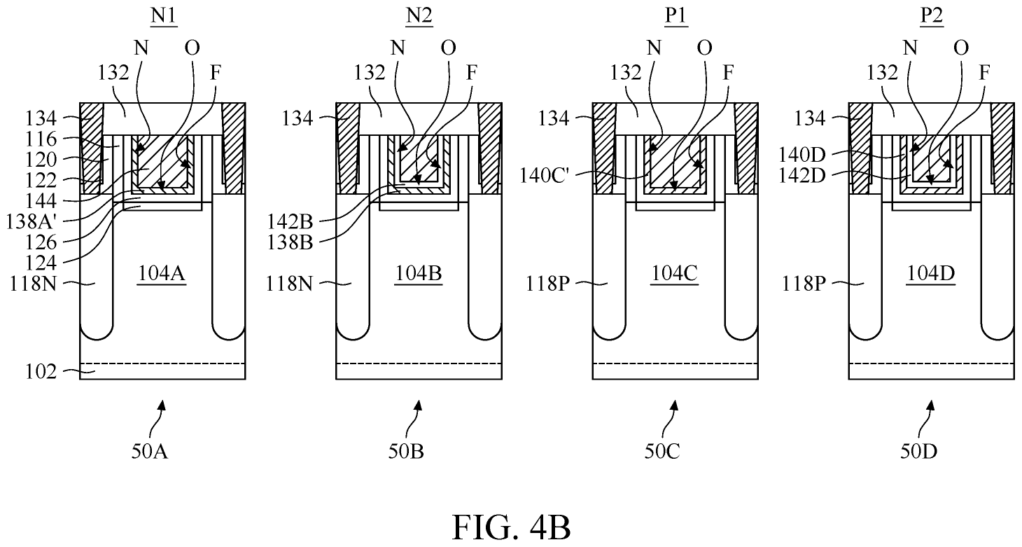

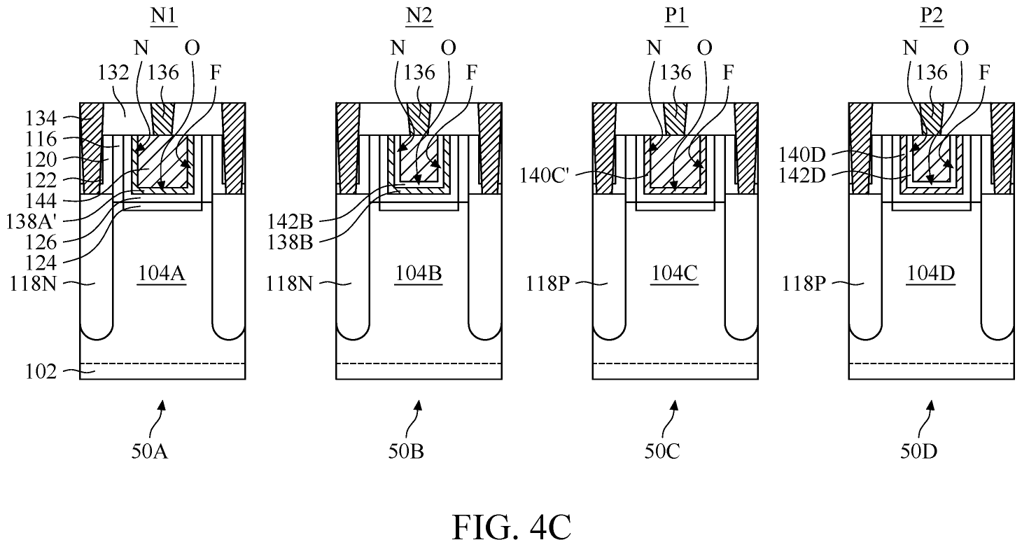

FIG. 4A illustrates the diffusion of dopants into the work function layers 138A and 140C during the deposition process for forming the gate metal fill layer 144, in accordance with some embodiments of the disclosure.

During the deposition process for forming the gate metal fill layer 144, the heat and/or ion bombardment from the deposition process drive impurities and/or dopants (e.g., oxygen, fluorine, nitrogen, etc.) to diffuse through the gate metal fill layer 144 and become doped or incorporated into the work function layer 138A and the work function layer 140C, as shown in FIG. 4A, in accordance with some embodiments. These impurities and/or dopants may come from the environment, reactive precursors in the deposition chamber, or they may remain in and/or on the semiconductor structure 100 after previous processes, in accordance with some embodiments.

Meanwhile, the protection layers 142B and 142D block impurities and/or dopants from diffusing into the work function layers 138B and 140D during the deposition process for forming the gate metal fill layer 144, as shown in FIG. 4A, in accordance with some embodiments.

The n-type work function layer 138A is doped to form a doped n-type work function layer 138A′, as shown in FIG. 4A, in accordance with some embodiments. In some embodiments, the concentration of the dopant (e.g., oxygen, fluorine and/or nitrogen) in the doped n-type work function layer 138A′ is greater than the concentration of the dopant in the non-doped n-type work function layer 138B.

The work function of the doped n-type work function layers 138A′ may increase and is higher than the work function of the non-doped n-type work function layers 138B, in accordance with some embodiments. That is, the difference between the EWF value of the gate stack and the conduction band energy of the channel material of the n-type transistor N1 is higher than the difference between the EWF value of the gate stack and the conduction band energy of the channel material of the n-type transistor N2, in accordance with some embodiments. As a result, the threshold voltage Vn1 of the n-type transistor N1 is higher than the threshold voltage Vn2 of the n-type transistor N2 (i.e., 0<Vn2<Vn1).

The p-type work function layer 140C is doped to form a doped p-type work function layer 140C′, as shown in FIG. 4A, in accordance with some embodiments. In some embodiments, the concentration of the dopant (e.g., oxygen, fluorine and/or nitrogen) in the doped p-type work function layer 140C′ is greater than the concentration of the dopant in the non-doped p-type work function layer 140D.

The work function of the doped p-type work function layers 140C′ may increase and is higher than the work function of the non-doped p-type work function layers 140D, in accordance with some embodiments. That is, the difference between the EWF value of the gate stack and the valence band energy of the channel material of the p-type transistor P1 is lower than the difference between the EWF value of the gate stack and the valence band energy of the channel material of the p-type transistor P2, in accordance with some embodiments. As a result, the absolute value of the threshold voltage Vp1 of the p-type transistor P1 is lower than the absolute value of the threshold voltage Vp2 of the p-type transistor P2 (i.e., Vp2<Vp1<0).

As the scale of semiconductor devices continues to shrink, one of the design challenges of semiconductor devices is to tune the threshold voltages of the semiconductor devices without degrading the gate-filling capability of the metal gate electrode layer. In accordance with some embodiments of the present disclosure, by doping or incorporating the dopants (e.g., oxygen, fluorine and/or nitrogen) into the work function layers 138 and/or 140 to shift the work functions of the work function layers 138 and/or 140, the threshold voltages of the NFETs and PFETs can be adjusted without varying the material and/or thickness of the work function layers 138 and/or 140. As a result, the transistors having different threshold voltages may be achieved on a single semiconductor substrate without degrading the gate-filling capability of the metal gate electrode layer. Therefore, the performance and the manufacturing yield of the resulting semiconductor device may improve.

In addition, one approach to manufacturing the p-type device with a low or ultra-low threshold is that the active region for the p-type device uses a different material than that of the active region for the n-type device, for example, silicon for an n-type device and silicon germanium for a p-type device. However, the material difference between the n-type and p-type active regions may lead to the difference in the etching amount between the n-type active region and the p-type active region in the etching process for forming the active regions, thereby resulting in the difference in the profile between the n-type and p-type active regions. Such profile differences will increase the difficulty of subsequent manufacturing processes. As a result, in accordance with the embodiments of the present disclosure, doping or incorporating the dopants (oxygen, fluorine and/or nitrogen) into the work function layers to further lower the threshold voltage of the p-type transistor P1 may be beneficial to realize the use of silicon as the active region 104C for the p-type transistor P1 instead of silicon germanium as the active region. Therefore, the difficulty of manufacturing the semiconductor device and the manufacturing yield of the resulting semiconductor device may improve.

FIGS. 4B and 4C illustrate the diffusion of dopants into work function layers 138A and 140C during the deposition process for forming the contact plugs 134 and the deposition process for forming the vias 136, in accordance with some embodiments of the disclosure.

Similarly, during the deposition process for forming the contact plugs 134 and the deposition process for forming the vias 136, the heat and/or ion bombardment from the deposition processes drive impurities and/or dopants (e.g., oxygen, fluorine, nitrogen, etc.) from the ambient and/or the reactive precursors to diffuse through the gate metal fill layer 144 and are doped or incorporated into the work function layer 138A′ and the work function layer 140C′, as shown in FIGS. 4B and 4C, in accordance with some embodiments. Meanwhile, the protection layers 142B and 142D block the impurities and/or dopants from diffusing into the work function layers 138B and 140D during the deposition process for forming the contact plugs 134 and the deposition process for forming the vias 136, in accordance with some embodiments.

FIG. 3G-3 is a plan view illustrating the metal gate electrode layers and neighboring components, in accordance with some embodiments of the disclosure. FIG. 3G-3 is taken along plan I-I shown in FIG. 3G-2. In some embodiments, the gate metal fill layer 144 of the n-type transistor N1 is surrounded by the work function layer 138A′ and has a dimension D1 in the Y direction. In some embodiments, the gate metal fill layer 144 of the n-type transistor N2 is surrounded by the protection layer 142B and has a dimension D2 in the Y direction. In some embodiments, the dimension D1 is greater than the dimension D2.

In some embodiments, the gate metal fill layer 144 of the p-type transistor P1 is surrounded by the work function layer 140C′ and has a dimension D3 in the Y direction. In some embodiments, the dimension D3 is greater than the dimension D2. In some embodiments, the gate metal fill layer 144 of the p-type transistor P2 is surrounded by the protection layer 142D and has a dimension D4 in the Y direction. In some embodiments, the dimension D4 is less than the dimension D3.

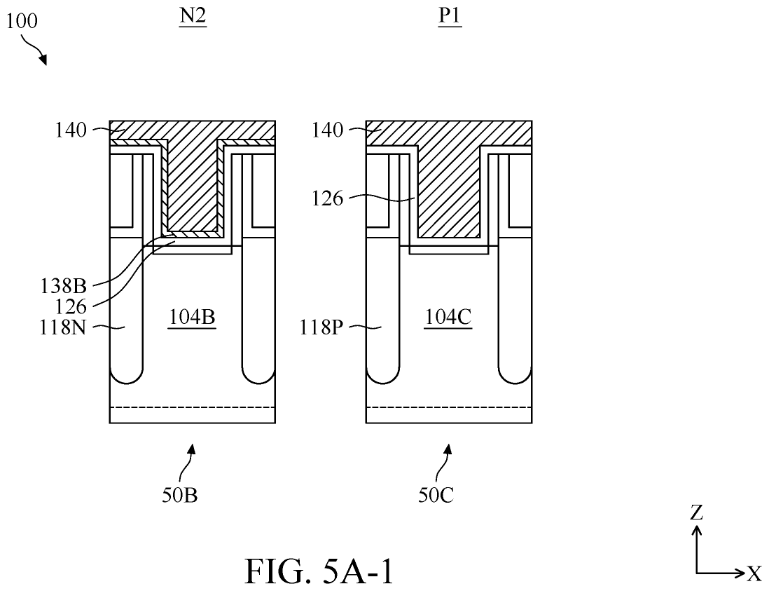

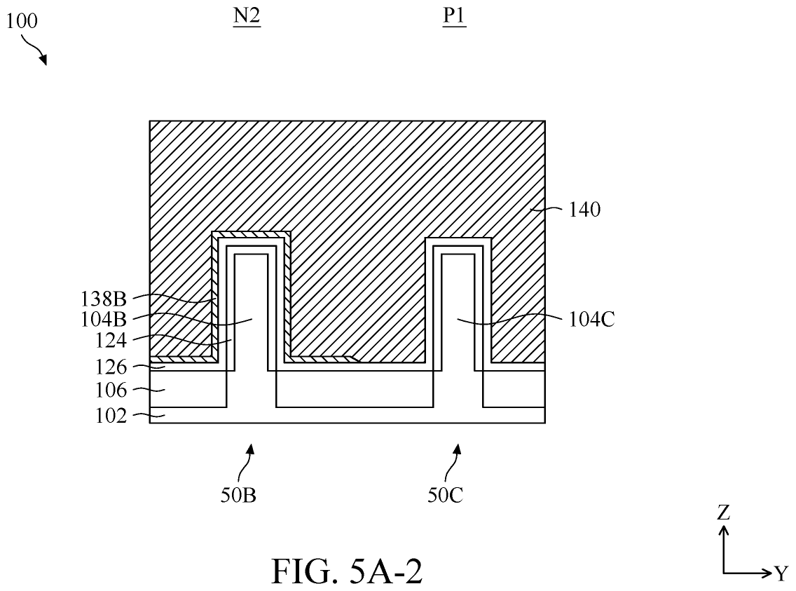

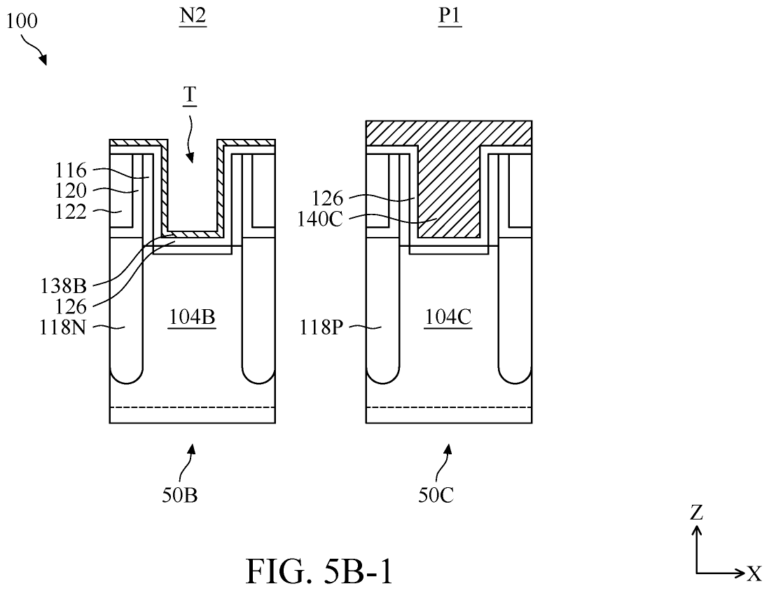

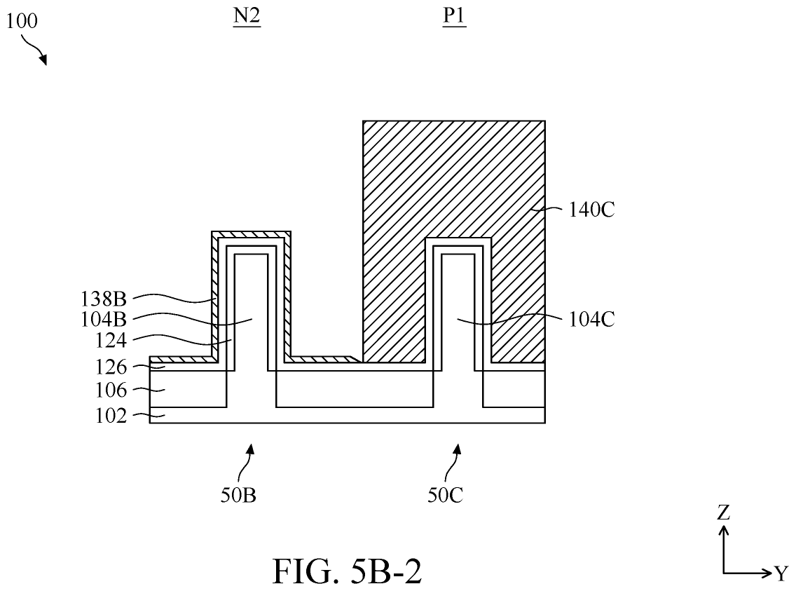

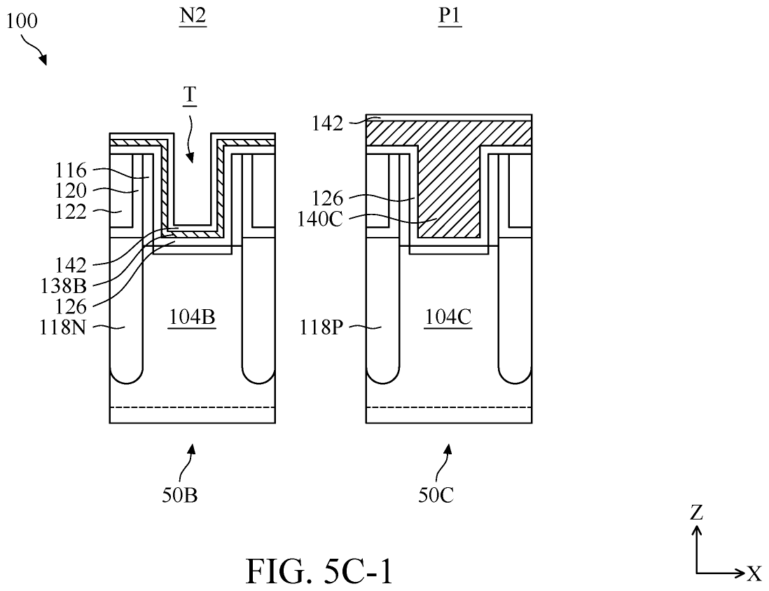

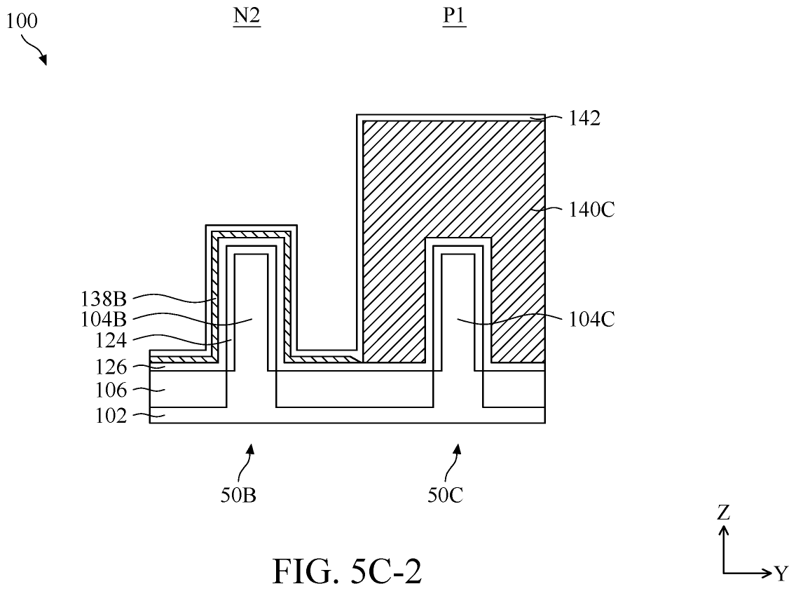

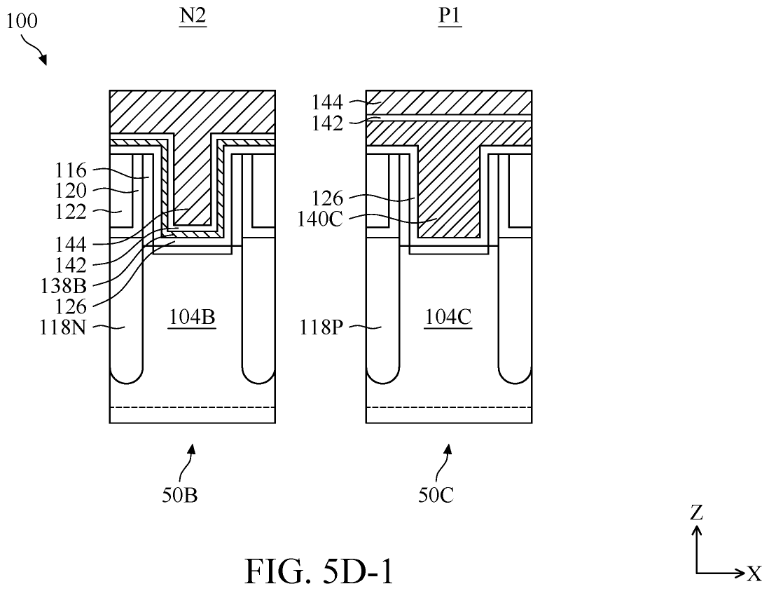

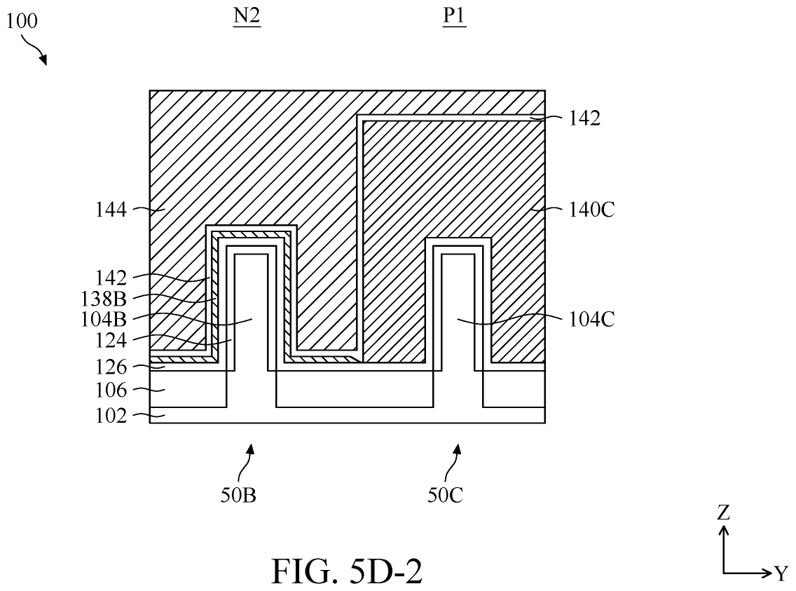

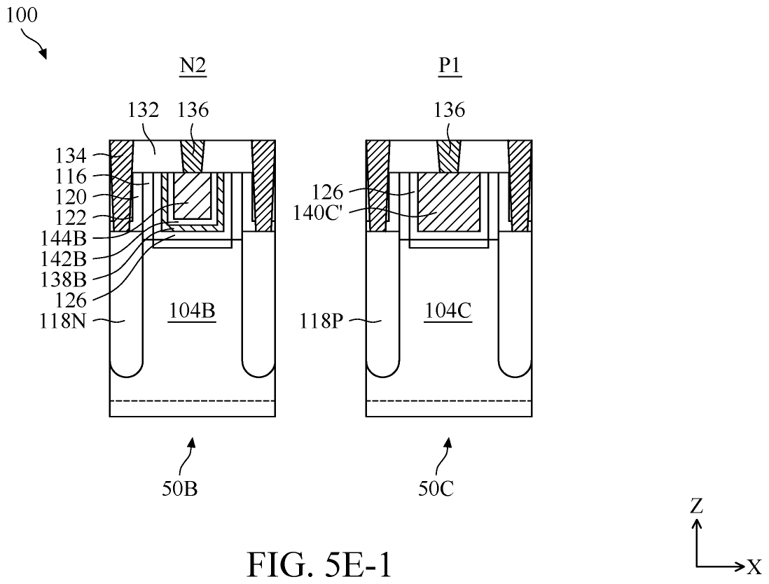

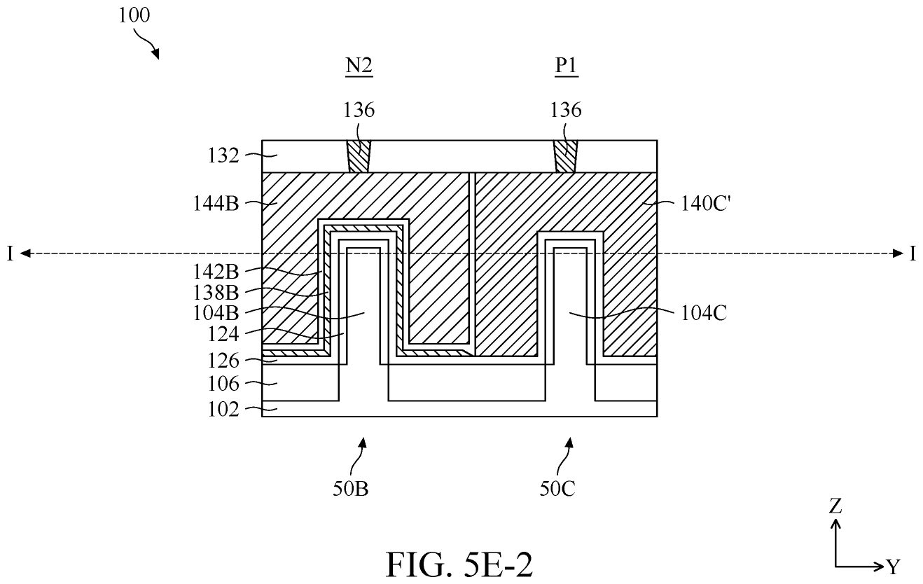

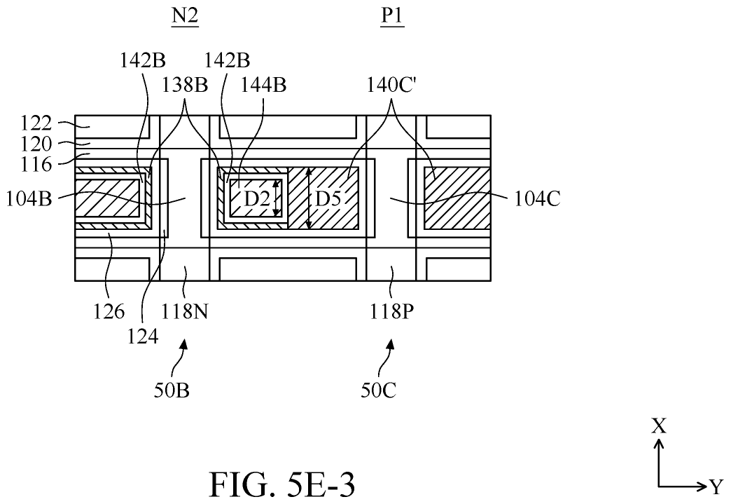

FIGS. 5A-1 through 5E-2 are cross-sectional views illustrating the formation of the metal gate electrode layers 128 (shown in FIGS. 2E-1 and 2E-2) for various types of transistors having different threshold voltages at various intermediate stages, in accordance with some embodiments of the disclosure. FIGS. 5A-1, 5B-1, 5C-1, 5D-1 and 5E-1 correspond to cross-section X-X of FIG. 1. FIGS. 5A-2, 5B-2, 5C-2, 5D-2 and 5E-2 correspond to cross-section Y-Y of FIG. 1. The embodiments of FIGS. 5A-1 through 5E-2 are similar to the embodiments of FIGS. 3A-1 through 3G-2 except that the metal gate electrode layer of the p-type transistor P1 has no gate metal fill layer 144.

The substrate 102 includes device regions 50B and 50C, as shown in FIGS. 5A-1 and 5A-2, in accordance with some embodiments. In some embodiments, an n-type transistor N2 is predetermined to be formed on the active region 104B in the device region 50B, and a p-type transistor P1 is predetermined to be formed on the active region 104C in the device region 50C.

Continuing from FIGS. 3B-1 and 3B-2, the work function layer 140 is formed over the semiconductor structure 100 at the device regions 50B and 50C to overfill the remainder of the gate trench T, as shown in FIGS. 5A-1 and 5A-2, in accordance with some embodiments. At the device region 50B, the work function layer 140 is formed on the work function layer 138B, in accordance with some embodiments. At the device region 50C, the work function layer 140 is formed on the gate dielectric layer 126, in accordance with some embodiments. In some embodiments, the material and the formation of the work function layer 140 is the same as or similar to that discussed in FIGS. 3C-1 and 3C-2.

FIGS. 5B-1 and 5B-2 illustrate the semiconductor structure after a patterning process, in accordance with some embodiments.

A patterning process is performed on the work function layer 140, as shown in FIGS. 5B-1 and 5B-2, in accordance with some embodiments. The patterning process includes forming a mask layer (not shown) over the work function layer 140 at the device region 50C, in accordance with some embodiments. The mask layer exposes the work function layer 140 at the device region 50B, in accordance with some embodiments. In some embodiments, the mask layer is a patterned photoresist layer or a patterned hard mask layer. The formation of the mask layer may be similar to the mask layer discussed above in FIGS. 3B-1 and 3B-2.

The patterning process also includes performing an etching process using the mask layer to remove the portion of the work function layer 140 at the device region 50B until the work function layer 138B is exposed, in accordance with some embodiments. The trench T is opened again, in accordance with some embodiments. The remaining portion of the work function layer 140 at the device region 50C denoted as a work function layer 140C. The etching process may be an anisotropic etching process such as dry plasma etching, an isotropic etching process such as dry chemical etching, remote plasma etching, wet chemical etching, or a combination thereof. In some embodiments, the mask layer is removed in the etching process or by an additional etching process or ashing process.

FIGS. 5C-1 and 5C-2 illustrate the semiconductor structure after the formation of a protection layer 142, in accordance with some embodiments.

A protection layer 142 is formed over the semiconductor structure 100 at the device regions 50B and 50C, as shown in FIGS. 5C-1 and 5C-2, in accordance with some embodiments. At the device region 50B, the protection layer 142 is formed on the work function layer 138B and partially fills the gate trench T, in accordance with some embodiments. At the device region 50C, the protection layer 142 is formed on the work function layer 140C, in accordance with some embodiments. In some embodiments, the protection layer 142 vertically extends along the sidewall of the work function layer 140C, as shown in FIG. 5C-2. In some embodiments, the material and the formation of the protection layer 142 is the same as or similar to that discussed in FIGS. 3E-1 and 3E-2.

FIGS. 5D-1 and 5D-2 illustrate the semiconductor structure after the formation of a gate metal fill layer 144, in accordance with some embodiments.

A gate metal fill layer 144 is formed over the protection layer 142 at the device regions 50B and 50C to overfill the remainder of the gate trench T, as shown in FIGS. 5D-1 and 5D-2, in accordance with some embodiments. In some embodiments, the material and the formation of the gate metal fill layer 144 is the same as or similar to that discussed in FIGS. 3G-1 and 3G-2.

FIGS. 5E-1 and 5E-2 illustrate the semiconductor structure after a planarization process and the formation of contact plugs 134 and a via 136, in accordance with some embodiments.

A planarization process discussed above in FIGS. 2D-1 and 2D-2 is performed to remove the gate dielectric layer 126, the work function layer 138B, the work function layer 140C, the protection layer 142 and the gate metal fill layer 144 formed over the upper surface of the first interlayer dielectric layer 122, as shown in FIGS. 5E-1 and 5E-2, in accordance with some embodiments. The remaining portion of the protection layer 142 at the device region 50B is denoted as a protection layer 142B, and the remaining portion of the gate metal fill layer 144 at the device region 50B is denoted as a gate metal fill layer 144B.

The steps discussed above in FIGS. 2E-1 and 2E-1 are performed, thereby forming the second interlayer dielectric layer 132, the contact plugs 134 and the vias 136, as shown in FIGS. 5E-1 and 5E-2, in accordance with some embodiments.

During the deposition process for forming the contact plugs 134 and the deposition process for forming the vias 136, the heat and/or ion bombardment from the deposition processes drive impurities and/or dopants (e.g., oxygen, fluorine, nitrogen, etc.) from the ambient and/or the reactive precursors to diffuse into the work function layer 140C, in accordance with some embodiments. Meanwhile, the protection layer 142B blocks impurities and dopants from diffusing into the work function layers 138B during the deposition process for forming the contact plugs 134 and the deposition process for forming the via 136, in accordance with some embodiments.

The doped p-type work function layers 140C is denoted as 140C′, as shown in FIGS. 5E-1 and 5E-2, in accordance with some embodiments. In some embodiments, the work function layer 138B, the protection layer 142B and the gate metal fill layer 144B combine to form the metal gate electrode layer of the n-type transistor N2. In some embodiments, the work function layer 140C′ is the metal gate electrode layer of the p-type transistor P1 and may also serve as the gate metal fill layer. Since the process for patterning the protection layer 142 is omitted, the cost of manufacturing the resulting semiconductor device may reduce, in accordance with some embodiments.

FIG. 5E-3 is a plan view illustrating the metal gate electrode layers and neighboring components, in accordance with some embodiments of the disclosure. FIG. 5E-3 is taken along plan I-I shown in FIG. 5E-2. In some embodiments, the protection layer 142B has a close-loop profile, and the gate metal fill layer 144B of the n-type transistor N2 is entirely surrounded by the close-loop profile of the protection layer 142B. In some embodiments, the work function layer 140C′ is separated from the gate metal fill layer 144B by the protection layer 142B. In some embodiments, the work function layer 140C′ has a dimension D5 in the Y direction. In some embodiments, the dimension D5 is greater than the dimension D2.

Although the embodiments described above are used in the semiconductor structure with FinFET design, the concept of the embodiments may be also used in a semiconductor device structure with another applicable design, e.g., planar FETs, dual-gate FETs, tri-gate FETs (e.g., nanostructure FETs (such as gate-all-around (GAA) FETs), forksheet FETs, ribbon FETs, multi-bridge channel (MBC) FETs, etc.).

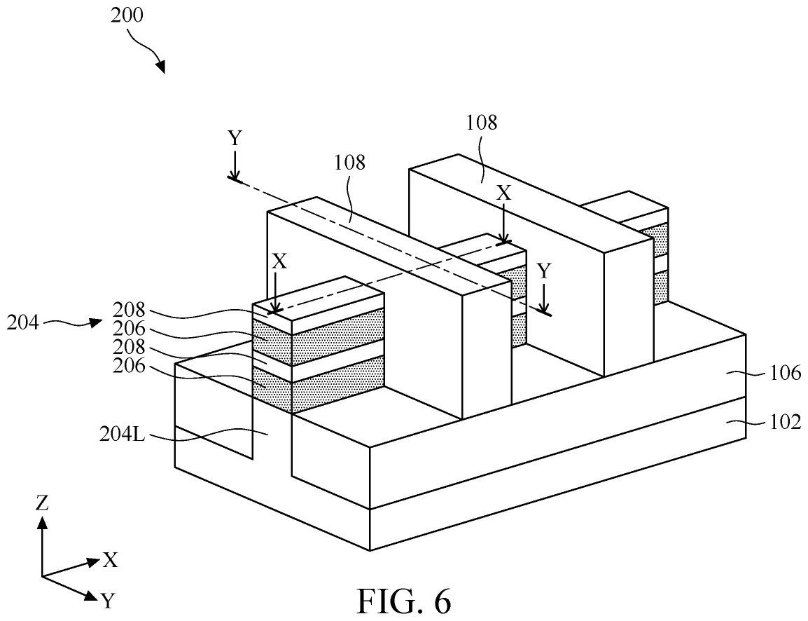

FIG. 6 is a perspective view of a semiconductor structure 200 with GAA design, in accordance with some embodiments of the disclosure.

The GAA transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The semiconductor structure 200 includes a substrate 102 and a fin structure 204 over the substrate 102, as shown in FIG. 6, in accordance with some embodiments. The fin structure 204 is the active region of the semiconductor structure 200, in accordance with some embodiments. The fin structure 204 includes a lower fin element 204L formed from the substrate 102, in accordance with some embodiments. The lower fin element 204L is surrounded by an isolation structure 106, in accordance with some embodiments. The fin structure 204 further includes an upper fin element formed from an epitaxial stack including alternating first semiconductor layers 206 and second semiconductor layer 208, in accordance with some embodiments. The second semiconductor layers 208 will form nanostructures (e.g., nanowires or nanosheets) and serve as the channel for the resulting semiconductor devices, in accordance with some embodiments.

The fin structure 204 extends in the X direction, in accordance with some embodiments. The fin structure 204 is defined as several channel regions and several source/drain regions, where the channel regions and the source/drain regions are alternately arranged, in accordance with some embodiments. Gate structures 108 are formed with longitudinal axes parallel to the Y direction and extending across or surrounding the channel regions of the fin structure 204, in accordance with some embodiments. The source/drain regions of the fin structure 204 are exposed from the gate structures 108, in accordance with some embodiments.

FIG. 6 further illustrates a reference cross-section that is used in later figures. Cross-section X-X is in a plane parallel to the longitudinal axis (X direction) and through the active region 204, in accordance with some embodiments. Cross-section Y-Y is in a plane parallel to the longitudinal axis (Y direction) of the gate structure and through the gate structure or gate stack (i.e., across the channel region of the fin structure 204), in accordance with some embodiments.

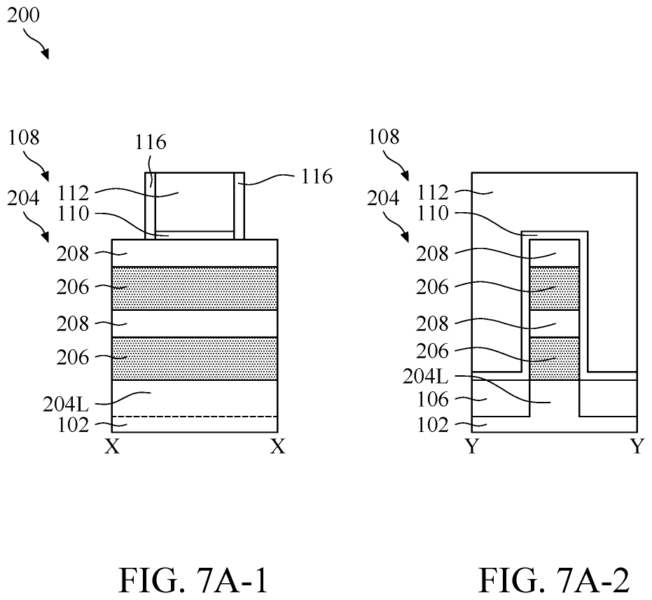

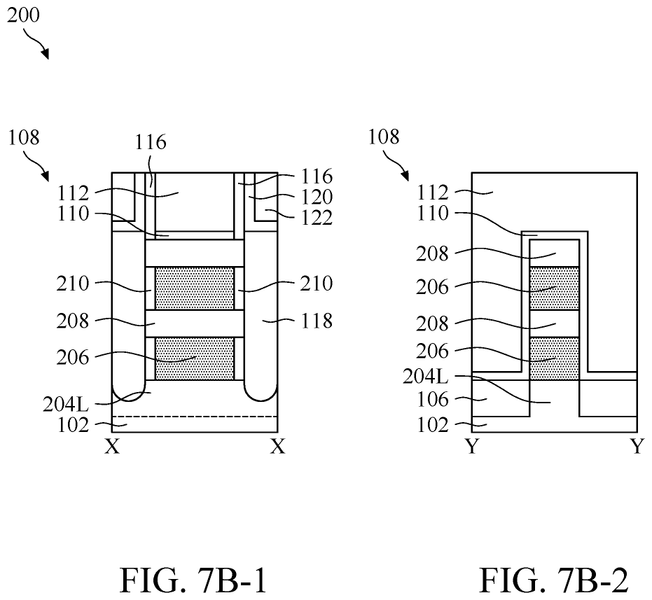

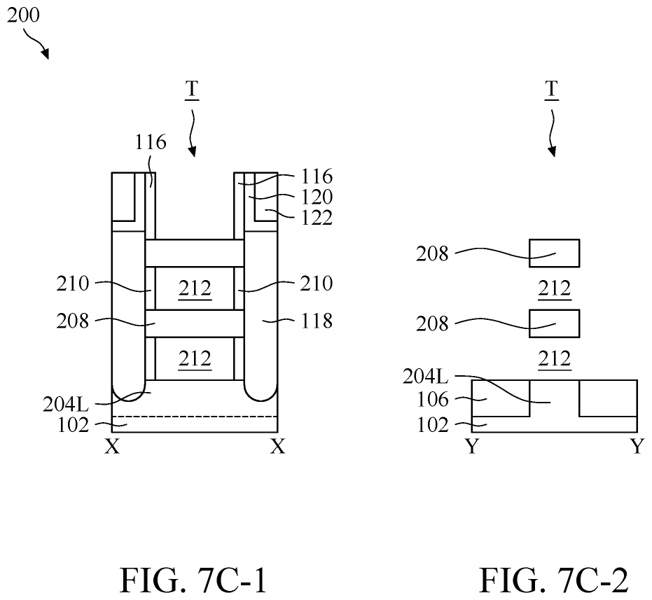

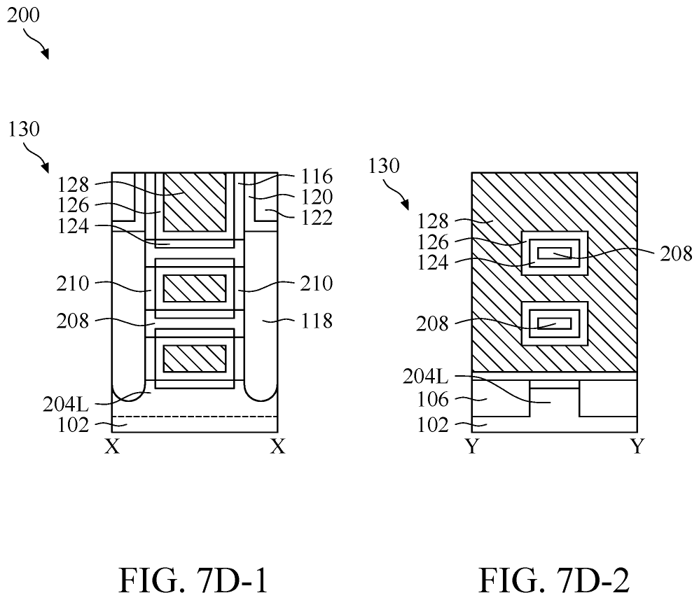

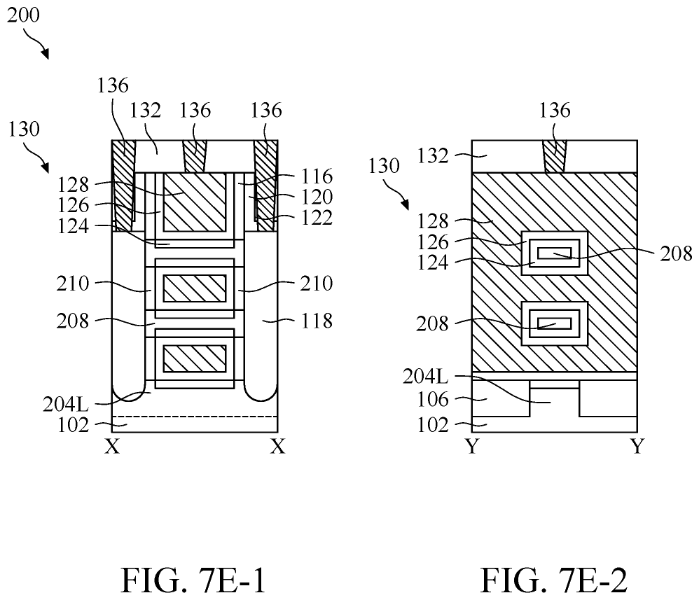

FIGS. 7A-1 through 7E-2 are cross-sectional views illustrating the formation of a semiconductor structure at various intermediate stages, in accordance with some embodiments of the disclosure. FIGS. 7A-1, 7B-1, 7C-1, 7D-1 and 7E-1 correspond to cross-section X-X of FIG. 6. FIGS. 7A-2, 7B-2, 7C-2, 7D-2 and 7E-2 correspond to cross-section Y-Y of FIG. 6.

FIGS. 7A-1 and 7A-2 illustrate a semiconductor structure 200 after the formation of an active region 204, an isolation structure 106, a gate structure 108 and gate spacer layers 116, in accordance with some embodiments.

The semiconductor structure 200 includes a substrate 102, active region 204 and an isolation structure 106 over the substrate 102, and dummy gate structure 108 over the active region 204 and the isolation structure 106, as shown in FIGS. 7A-1 and 7A-2, in accordance with some embodiments. The formation of the active region 204 includes forming an epitaxial stack over the substrate 102 using an epitaxial growth process, in accordance with some embodiments. The epitaxial stack includes alternating first semiconductor layers 206 and second semiconductor layers 208, in accordance with some embodiments. The epitaxial growth process may be MBE, MOCVD, or VPE, or another suitable technique.

In some embodiments, the first semiconductor layers 206 are made of a first semiconductor material and the second semiconductor layers 208 are made of a second semiconductor material. The first semiconductor material for the first semiconductor layers 206 has a different lattice constant than the second semiconductor material for the second semiconductor layers 208, in accordance with some embodiments. In some embodiments, the first semiconductor material and the second semiconductor material have different oxidation rates and/or etching selectivity. In some embodiments, the first semiconductor layers 206 are made of SiGe, where the percentage of germanium (Ge) in the SiGe is in a range from about 20 atomic % to about 50 atomic %, and the second semiconductor layers 208 are made of pure or substantially pure silicon. In some embodiments, the first semiconductor layers 206 are Si₁₋ₓGeₓ, where x is more than about 0.3, or Ge (x=1.0) and the second semiconductor layers 208 are Si or Si_{1-y}Ge_{y}, where y is less than about 0.4, and x>y.

The first semiconductor layers 206 are configured as sacrificial layers and will be removed to form gaps to accommodate gate materials, and the second semiconductor layers 208 will form nanostructures (e.g., nanowires or nanosheets) that laterally extend between source/drain features and serve as the channel layers for the resulting semiconductor devices (such as nanostructure transistors), in accordance with some embodiments.

The formation of the active region 204 further includes patterning the epitaxial stack and underlying substrate 102 using photolithography and etching processes, thereby forming trenches and the active region 204 protruding from between trenches, in accordance with some embodiments. The portion of substrate 102 protruding from between the trenches serves as the lower fin element 204L of the active region 204, in accordance with some embodiments. A remainder of the epitaxial stack (including the first semiconductor layers 206 and the second semiconductor layers 208) serves as the upper fin elements of the active region 204, in accordance with some embodiments. In some embodiments, the active region 204 is the fin structure 204 as shown in FIG. 6.

In some embodiments, the thickness of each of the first semiconductor layers 206 is in a range from about 6 nm to about 16 nm. In some embodiments, the thickness of each of the second semiconductor layers 208 is in a range from about 4 nm to about 8 nm. The thickness of the second semiconductor layers 208 may be greater than, equal to, or less than the first semiconductor layers 206, depending on the amount of gate materials to be filled in spaces where the first semiconductor layers 206 are removed. Although two first semiconductor layers 206 and two second semiconductor layers 208 are shown in FIGS. 7A-1 and 7A-2, the number is not limited to two, and can be one or three, and is less than 10.

An isolation structure 106 is formed to surround the lower fin element 204L of the active region 204, as shown in FIG. 7A-2, in accordance with some embodiments. A dummy gate structure 108 is formed across the active region 204 and the isolation structure 106, as shown in FIGS. 7A-1 and 7A-2, in accordance with some embodiments. Gate spacer layers 116 are formed along the opposite sidewalls of the dummy gate structure 108, as shown in FIGS. 7A-1 through 7A-2, in accordance with some embodiments. The material and the formation of the isolation structure 106, the dummy gate structure 108 and the gate spacer layers 116 may be the same as or similar to that of the isolation structure 106, the dummy gate structure 108 and the gate spacer layers 116 described above in FIGS. 2A-1 and 2A-2, in accordance with some embodiments.

FIGS. 7B-1 and 7B-2 illustrate a semiconductor structure 200 after the formation of source/drain features 118, inner spacer layers 210, a contact etching stop layer 120 and a first interlayer dielectric layer 122, in accordance with some embodiments.

After the source/drain recesses are formed, an etching process is performed to laterally recess, from the source/drain recesses, the first semiconductor layers 206 of the active region 204, thereby forming notches, and then inner spacer layers 210 are formed in the notches, as shown in FIG. 7B-1, in accordance with some embodiments.

The inner spacer layers 210 are formed to abut the recessed side surfaces of the first semiconductor layers 206, in accordance with some embodiments. In some embodiments, the inner spacer layers 210 are located between adjacent second semiconductor layers 208 and between the lowermost second semiconductor layer 208 and the lower fin element 204L. In some embodiments, the inner spacer layers 210 extend directly below the gate spacer layers 116, in accordance with some embodiments.

The inner spacer layers 210 may avoid the source/drain features and the gate stack from being in direct contact and are configured to reduce the parasitic capacitance between the gate stack and the source/drain features (i.e., Cgs and Cgd), in accordance with some embodiments. In some embodiments, the inner spacer layers 210 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), or oxygen-doped silicon carbonitride (Si(O)CN).

In some embodiments, the inner spacer layers 210 are formed by depositing a dielectric material for the inner spacer layers 210 over the semiconductor structure 200 to fill the notches, and then etching back the dielectric material to remove the dielectric material outside the notches. Portions of the dielectric material left in the notches serve as the inner spacer layers 210, in accordance with some embodiments. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching, wet chemical etching, or a combination thereof.

Afterward, source/drain features 118 are grown in the source/drain recesses on the exposed surfaces of the lower fin element 204L, as shown in FIG. 7B-1, in accordance with some embodiments. A contact etching stop layer 120 is formed over the semiconductor structure 200 to cover the source/drain features 118, as shown in FIG. 7B-1, in accordance with some embodiments. A first interlayer dielectric layer 122 is formed over the contact etching stop layer 120, as shown in FIG. 7B-1, in accordance with some embodiments. The material and the formation of the source/drain features 118, the contact etching stop layer 120 and the first interlayer dielectric layer 122 may be the same as or similar to that of the source/drain features 118, the contact etching stop layer 120 and the first interlayer dielectric layer 122 described above in FIGS. 2B-1 and 2B-2, in accordance with some embodiments.

FIGS. 7C-1 and 7C-2 illustrate a semiconductor structure 200 after the removal of the dummy gate structure 108 and the first semiconductor layers 206, in accordance with some embodiments.

One or more etching processes are performed to remove the dummy gate structure 108 to form a gate trench T and remove the first semiconductor layers 206 of the active region 204 to form gaps 212, in accordance with some embodiments. In some embodiments, the gate trench T exposes the sidewalls of the gate spacer layers 116 facing the channel region, in accordance with some embodiments. In some embodiments, the gaps 212 expose the sidewalls of the inner spacer layers 210 facing the channel region. The one or more etching processes may include an anisotropic etching process such as dry plasma etching, an isotropic etching process such as dry chemical etching, remote plasma etching, wet chemical etching, or a combination thereof.

After the one or more etching processes, the four main surfaces of the second semiconductor layers 208 are exposed, in accordance with some embodiments. The exposed second semiconductor layers 208 form nanostructures 208, in accordance with some embodiments. The nanostructures 208 are vertically stacked and spaced apart from one other, in accordance with some embodiments. As the term is used herein, “nanostructures” refers to the semiconductor layers with cylindrical shape, bar shaped or sheet shape. The nanostructures 208 function as channel layers of the resulting semiconductor devices (e.g., nanostructure transistors such as GAA transistors), in accordance with some embodiments.

FIGS. 7D-1 and 7D-2 illustrate a semiconductor structure 200 after the formation of a final gate stack 130, in accordance with some embodiments.

The final gate stack 130 is formed in the gate trench T and gaps 212, thereby wrapping around the nanostructures 208, as shown in FIGS. 7D-1 and 7D-2, in accordance with some embodiments. The final gate stack 130 includes an interfacial layer 124, a gate dielectric layer 126 and a metal gate electrode layer 128, as shown in FIGS. 7D-1 and 7D-2, in accordance with some embodiments.

The interfacial layer 124 wraps around the nanostructures 208, in accordance with some embodiments. Semiconductor material from the nanostructures 208 and the lower fin elements 204L is oxidized to form the interfacial layer 124, in accordance with some embodiments. The gate dielectric layer 126 is formed conformally along the interfacial layer 124 to wrap around the nanostructures 208, in accordance with some embodiments. The gate dielectric layer 126 is further conformally formed along the sidewalls of the inner spacer layers 210 facing the channel region, in accordance with some embodiments. The deposition of the capping layer(s) and the anneal processes as described above in FIGS. 2D-1 and 2D-2 may be performed on the semiconductor structure 200. The metal gate electrode layer 128 is formed to fill remainders of the gate trench T and the gaps 212, in accordance with some embodiments. The formation of the final gate stack 130 may be the same as or similar to the formation of the final gate stack 130 described above in FIGS. 2D-1 and 2D-2, in accordance with some embodiments.

A planarization process such as CMP is performed on the semiconductor structure 200 to remove the final gate stack 130 formed over the upper surface of the first interlayer dielectric layer 122, in accordance with some embodiments.

The final gate stack 130 surrounds the nanostructures 208 and are interposed between the source/drain features 118, in accordance with some embodiments. The final gate stack 130 combines with the source/drain features 118 and the nanostructures 208 to form a nanostructure device, such as an n-channel GAAFET device or a p-channel GAAFET device, in accordance with some embodiments. The final gate stack 130 may engage the channel region of the nanostructures 208, so that current can flow between the source/drain features 118 during operation.

FIGS. 7E-1 and 7E-2 illustrate a semiconductor structure 200 after the formation of a second interlayer dielectric layer 132, contact plugs 134 and a via 136, in accordance with some embodiments.

A second interlayer dielectric layer 132 is formed over the semiconductor structure 200, as shown in FIGS. 7E-1 and 7E-2, in accordance with some embodiments. Contact plugs 134 are formed in and/or through the second interlayer dielectric layer 132, the first interlayer dielectric layer 122 and the contact etching stop layer 120 and land on the source/drain features 118, in accordance with some embodiments. A via 136 is formed in and/or through the second interlayer dielectric layer 132 and land on the metal gate electrode layer 128 of the final gate stack 130, in accordance with some embodiments. The material and the formation of the second interlayer dielectric layer 132, the contact plugs 134 and the via 136 may be the same as or similar to that of the second interlayer dielectric layer 132, the contact plugs 134 and the via 136 described above in FIGS. 2E-1 and 2E-2, in accordance with some embodiments.

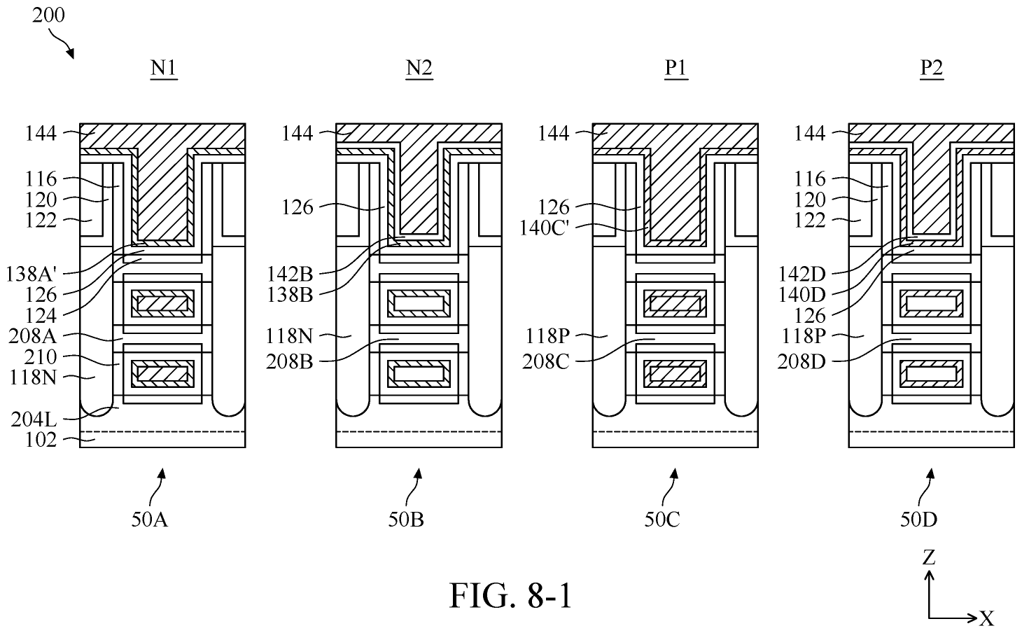

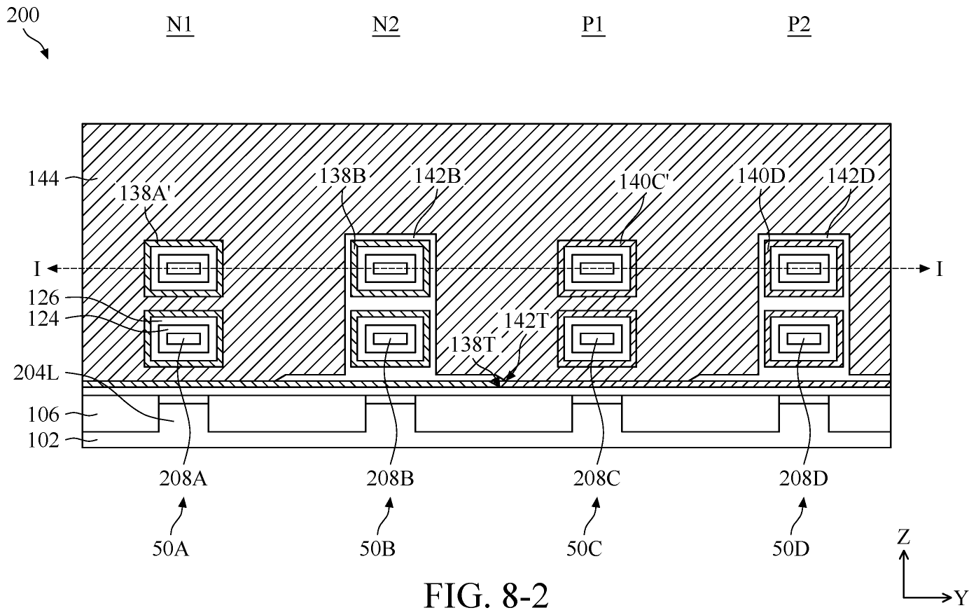

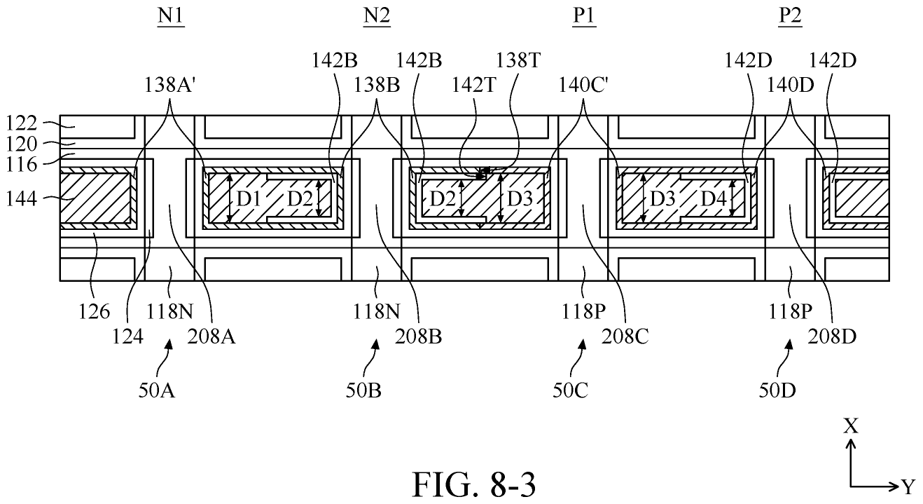

Although FIGS. 7E-1 and 7E-2 only show one transistor of the semiconductor structure 200, the semiconductor structure 200 may include various types of transistors having different threshold voltages. FIGS. 8-1 and 8-2 are cross-sectional views illustrating the metal gate electrode layers 128 (shown in FIGS. 2E-1 and 2E-2) for various types of transistors having different threshold voltages and neighboring components, in accordance with some embodiments of the disclosure. FIG. 8-1 corresponds to cross-section X-X of FIG. 6. FIG. 8-2 corresponds to cross-section Y-Y of FIG. 6.

The substrate 102 includes device regions 50A, 50B, 50C and 50D, as shown in FIGS. 8-1 and 8-2, in accordance with some embodiments. The nanostructures formed in the device regions 50A, 50B, 50C and 50D are denoted as nanostructures 208A, 208B, 208C and 208D, respectively, in accordance with some embodiments. In some embodiments, an n-type transistor N1 is formed on the nanostructures 208A in the device region 50A and has a threshold voltage Vn1 (e.g., standard). In some embodiments, an n-type transistor N2 is formed on the nanostructures 208B in the device region 50B and has a threshold voltage Vn2 (e.g., low voltage or ultra-low voltage). Here, 0<Vn2<Vn1.

In some embodiments, a p-type transistor P1 is formed on the nanostructures 208C in the device region 50C and has a threshold voltage Vp1 (e.g., low voltage or ultra-low voltage). In some embodiments, a p-type transistor P2 is formed on the nanostructures 208D in the device region 50D and has a threshold voltage Vp2 (e.g., standard voltage). Here, Vp2<Vp1<0.

In some embodiments, the n-type transistors N1 and N2 are n-channel GAA FETs, and the p-type transistors P1 and P2 are p-channel GAA FETs. The source/drain features 118 formed in the device regions 50A and 50B are n-type source/drain features and denoted as source/drain features 118N, and the source/drain features 118 formed in the device regions 50C and 50D are p-type source/drain features and denoted as source/drain features 118P, in accordance with some embodiments.

In some embodiments, the metal gate electrode layer of the n-type transistor N1 includes a doped n-type work function layer 138A′ and a gate metal fill layer 144. In some embodiments, the metal gate electrode layer of the n-type transistor N2 includes a non-doped n-type work function layer 138B, a protection layer 142B and the gate metal fill layer 144. In some embodiments, the concentration of the dopant (e.g., oxygen, fluorine and/or nitrogen) in the doped n-type work function layer 138A′ is greater than the concentration of the dopant in the non-doped n-type work function layer 138A.

In some embodiments, the metal gate electrode layer of the p-type transistor P1 includes a doped p-type work function layer 140C′ and the gate metal fill layer 144. In some embodiments, the metal gate electrode layer of the p-type transistor P2 includes a non-doped p-type work function layer 140D, a protection layer 142D, and the gate metal fill layer 144. In some embodiments, the concentration of the dopant (e.g., oxygen, fluorine and/or nitrogen) in the doped p-type work function layer 140C′ is greater than the concentration of the dopant in the non-doped p-type work function layer 140D.

The material and the formation of the work function layer 138 (including 138A′ and 138B), the work function layer 140 (including 140C′ and 140D), the protection layer 142 (including 142B and 142D) and the gate metal fill layer 144 may be the same as or similar to that of the work function layer 138, the work function layer 140, the protection layer 142 and the gate metal fill layer 144 described above in FIGS. 3A-1 and 3G-2, in accordance with some embodiments.

During the deposition process for forming the gate metal fill layer 144 (and/or forming the contact plugs 134 and/or the deposition process for forming the vias 136), the heat and/or ion bombardment from the deposition process drive impurities and/or dopants (e.g., oxygen, fluorine, nitrogen, etc.) to diffuse through the gate metal fill layer 144 and become doped or incorporated into the work function layer 138A and the work function layer 140C, thereby forming the doped work function layer 138A′ and the doped work function layer 140C′, in accordance with some embodiments. Meanwhile, the protection layers 142B and 142D block the impurities and/or dopants from diffusing into the work function layers 138B and 140D, in accordance with some embodiments.

The work function of the doped n-type work function layers 138A′ is higher than the work function of the non-doped n-type work function layers 138B, in accordance with some embodiments. As a result, the difference between the EWF value of the gate stack and the conduction band energy of the channel material of the n-type transistor N1 is higher than the difference between the EWF value of the gate stack and the conduction band energy of the channel material of the n-type transistor N2, in accordance with some embodiments.

The work function of the doped p-type work function layers 140C′ is higher than the work function of the non-doped p-type work function layers 140D, in accordance with some embodiments. As a result, the difference between the EWF value of the gate stack and the valence band energy of the channel material of the p-type transistor P2 is lower than the difference between the EWF value of the gate stack and the valence band energy of the channel material of the p-type transistor P1, in accordance with some embodiments.

The protection layer 142B overfills the gaps between the nanostructures 208B, and the protection layer 142D overfills the gaps between the nanostructures 208D, in accordance with some embodiments. The gaps between the nanostructures 208B are free of the gate metal fill layer 144, and the gaps between the nanostructures 208D are free of the gate metal fill layer 144, in accordance with some embodiments. In alternative embodiments, the protection layer 142B and 142D may partially fill the gaps between the nanostructures 208B and the gaps between the nanostructures 208D, and the gate metal fill layer 144 may extend in these gaps.

In some embodiments, the protection layer 142B extends beyond the terminus 138T of the work function layer 138B. In some embodiments, the terminus 142T of the protection layer 142B is located closer to the sidewalls of the active region 104C than the terminus 138T of the work function layer 138B.

FIG. 8-3 is a plan view illustrating the metal gate electrode layers and neighboring components, in accordance with some embodiments of the disclosure. FIG. 8-3 is taken along plan I-I shown in FIG. 8-2. In some embodiments, the gate metal fill layer 144 of the n-type transistor N1 is surrounded by the work function layer 138A′ and has a dimension D1 in the Y direction. In some embodiments, the gate metal fill layer 144 of the n-type transistor N2 is surrounded by the protection layer 142B and has a dimension D2 in the Y direction. In some embodiments, the dimension D1 is greater than the dimension D2.

In some embodiments, the gate metal fill layer 144 of the p-type transistor P1 is surrounded by the work function layer 140C′ and has a dimension D3 in the Y direction. In some embodiments, the dimension D3 is greater than the dimension D2. In some embodiments, the gate metal fill layer 144 of the p-type transistor P2 is surrounded by the protection layer 142D and has a dimension D4 in the Y direction. In some embodiments, the dimension D4 is less than the dimension D3.

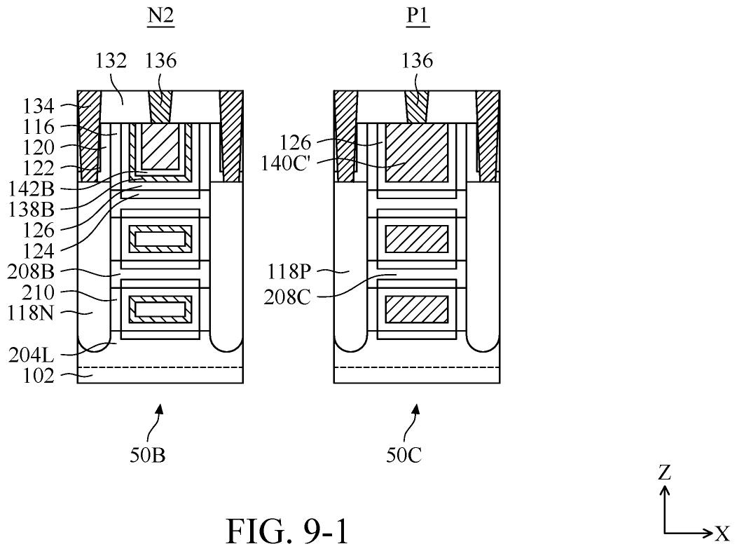

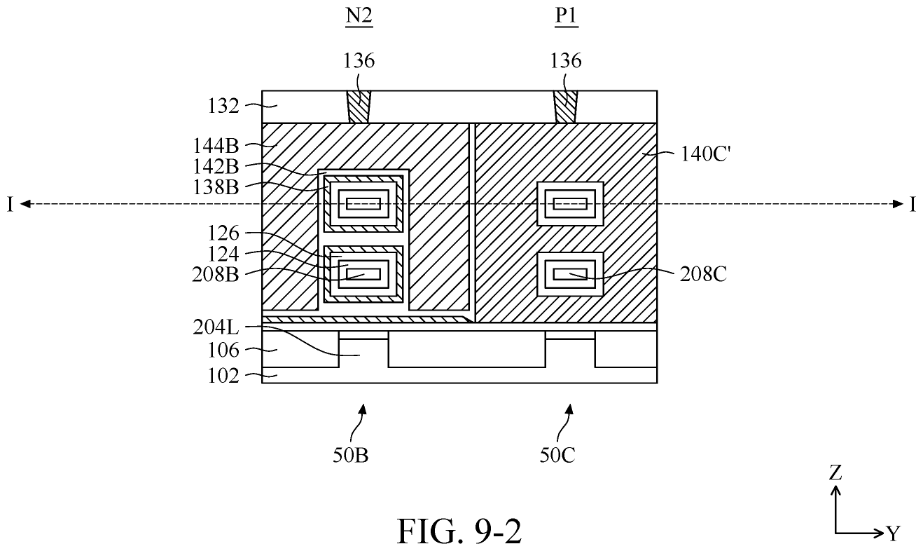

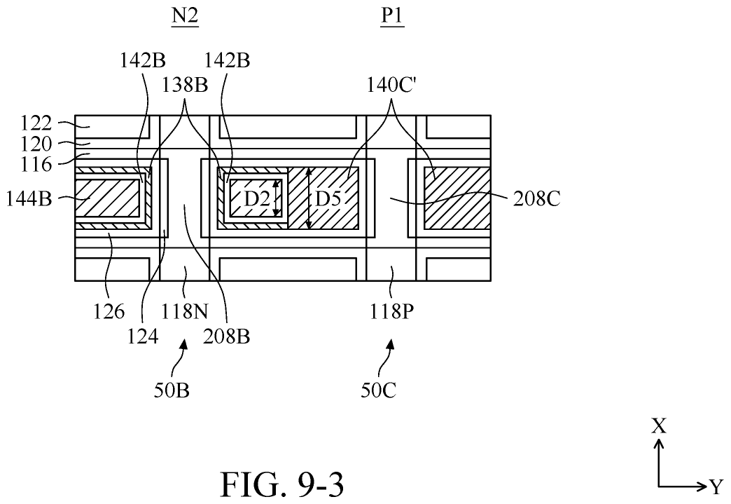

FIGS. 9-1 and 9-2 are cross-sectional views illustrating the metal gate electrode layers 128 (shown in FIGS. 2E-1 and 2E-2) for various types of transistors having different threshold voltages and neighboring components, in accordance with some embodiments of the disclosure. FIG. 9-1 corresponds to cross-section X-X of FIG. 6. FIG. 9-2 corresponds to cross-section Y-Y of FIG. 6.

The substrate 102 includes device regions 50B and 50C, as shown in FIGS. 9-1 and 9-2, in accordance with some embodiments. In some embodiments, an n-type transistor N2 is formed on the nanostructures 208B in the device region 50B, and a p-type transistor P1 is formed on the nanostructures 208C in the device region 50C. In some embodiments, the metal gate electrode layer of the n-type transistor N2 includes the non-doped n-type work function layer 138B, the protection layer 142B and the gate metal fill layer 144B. In some embodiments, the metal gate electrode layer of the p-type transistor P1 includes the doped p-type work function layer 140C′, which may also serve as the gate metal fill layer.

The material and the formation of the non-doped n-type work function layer 138B, the doped p-type work function layer 140C′, the protection layer 142B and the gate metal fill layer 144B may be the same as or similar to that of the work function layer 138B, the work function layer 140C′, the protection layer 142B and the gate metal fill layer 144B described above in FIGS. 5A-1 through 5E-2, in accordance with some embodiments.

During the deposition process for forming the contact plugs 134 and the deposition process for forming the vias 136, the heat and/or ion bombardment from the deposition processes drive impurities and/or dopants (e.g., oxygen, fluorine, nitrogen, etc.) from the ambient and/or the reactive precursors to diffuse into the work function layer 140C, thereby forming the doped work function layer 140C′, in accordance with some embodiments. Meanwhile, the protection layer 142B blocks impurities and dopants from diffusing into the work function layers 138B, in accordance with some embodiments.

FIG. 9-3 is a plan view illustrating the metal gate electrode layers and neighboring components, in accordance with some embodiments of the disclosure. FIG. 9-3 is taken along plan I-I shown in FIG. 9-2. In some embodiments, the protection layer 142B has a close-loop profile, the gate metal fill layer 144B of the n-type transistor N2 is entirely surrounded by the close-loop profile of the protection layer 142B. In some embodiments, the work function layer 140C′ is separated from the gate metal fill layer 144B by the protection layer 142B. In some embodiments, the work function layer 140C′ has a dimension D5 in the Y direction. In some embodiments, the dimension D5 is greater than the dimension D2.

As described above, a semiconductor structure having various devices with different threshold voltages and a method for forming the same are provided. The aspect of the present disclosure is direct to tuning the threshold voltages of the semiconductor devices. The method for forming the semiconductor structure includes doping dopants (e.g., oxygen, fluorine and/or nitrogen) into the n-type work function layer 138 and/or the p-type work function layers 140 to shift the work functions of the work function layers 138 and/or 140. The threshold voltages of the NFETs and PFETs can be adjusted without varying the material and/or thickness of the work function layers 138 and/or 140. As a result, the transistors having different threshold voltages may be achieved on a single semiconductor substrate without degrading the gate-filling capability of the metal gate electrode layer. Therefore, the performance and the manufacturing yield of the resulting semiconductor device may improve.

Embodiments of a method for forming a semiconductor structure are provided. The method may include forming a protection layer over the n-type work function layer while exposing the p-type work function layer, and diffusing a dopant into the p-type work function layer while the first protection layer blocks the dopant from diffusing into the n-type work function layer. Therefore, the threshold voltage of the p-type transistor may be lowered, which may be beneficial to realize the use of silicon as the active region for the p-type transistor.

In some embodiments, a method for forming a semiconductor structure is provided. The method includes forming a first active region and a second active region over a first n-type device region and a first p-type device region of a substrate, respectively. The method includes forming a first n-type work function layer and a first p-type work function layer along the first active region and the second active region, respectively. The method includes forming a semiconductor material along the first n-type work function layer and the first p-type work function layer. The method includes removing a first portion of the semiconductor material along the first p-type work function layer, thereby leaving a second portion of the semiconductor material as a first protection layer over the first n-type work function layer. The method includes diffusing a dopant into the first p-type work function layer to form a doped p-type work function layer while the first protection layer blocks the dopant from diffusing into the first n-type work function layer.

In some embodiments, a method for forming a semiconductor structure is provided. The method includes forming a first active region and a second active region over a substrate. The method includes forming a dummy gate structure across the first active region and the second active region. The method includes removing the dummy gate structure to form a trench. The method includes forming a first work function layer on the first active region in the trench. The method includes forming a second work function layer on the second active region in the trench. The method includes forming a protection layer on the first work function layer in the trench while exposing the second work function layer. The method includes forming a metal fill layer on the protection layer and the second work function layer to overfill the trench. A dopant diffuses through the metal fill layer and into the second work function layer during formation of the metal fill layer.

In some embodiments, a semiconductor structure is provided. The semiconductor structure includes a first n-type transistor and a first p-type transistor adjacent to the first n-type transistor. The first n-type transistor includes a first active region extending in a first direction, a first gate dielectric layer over the first active region, and a first n-type work function layer over the first gate dielectric layer, a first protection layer over the first n-type work function layer, and a first metal fill layer over the first protection layer. The first p-type transistor includes a second active region extending in the first direction, a second gate dielectric layer over the second active region, a first p-type work function layer over the first gate dielectric layer, and a second metal fill layer over the first p-type work function layer. The first p-type work function layer is doped with oxygen, fluorine, or nitrogen.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first active region and a second active region over a first n-type device region and a first p-type device region of a substrate, respectively;
forming a first n-type work function layer and a first p-type work function layer along the first active region and the second active region, respectively;
forming a semiconductor material along the first n-type work function layer and the first p-type work function layer;
removing a first portion of the semiconductor material along the first p-type work function layer, thereby leaving a second portion of the semiconductor material as a first protection layer over the first n-type work function layer; and
diffusing a dopant into the first p-type work function layer to form a doped p-type work function layer while the first protection layer blocks the dopant from diffusing into the first n-type work function layer.

2. The method for forming the semiconductor structure as claimed in claim 1, wherein the semiconductor material is silicon.

3. The method for forming the semiconductor structure as claimed in claim 1, wherein the thickness of the first n-type work function layer is thicker than a thickness of the semiconductor material.

4. The method for forming the semiconductor structure as claimed in claim 1, wherein the dopant includes oxygen, fluorine, or nitrogen.

5. The method for forming the semiconductor structure as claimed in claim 1, further comprising:
forming a third active region over a second p-type device region of the substrate; and
forming a second p-type work function layer along the third active region, wherein the semiconductor material is further formed along the second p-type work function layer, and the first portion of the semiconductor material along the first p-type work function layer is removed, thereby leaving a third portion of the semiconductor material as a second protection layer over the second p-type work function layer.

6. The method for forming the semiconductor structure as claimed in claim 5, wherein the second protection layer blocks the dopant from diffusing into the second p-type work function layer while the dopant is diffused into the first p-type work function layer, and a work function of the doped p-type work function layer is different than a work function of the second p-type work function layer.

7. The method for forming the semiconductor structure as claimed in claim 1, further comprising:
forming a third active region over a second n-type device region of the substrate;
forming a second n-type work function layer along the third active region, wherein the semiconductor material is further formed along the second n-type work function layer; and
removing a third portion of the semiconductor material along the second n-type work function layer.

8. The method for forming the semiconductor structure as claimed in claim 7, further comprising:
diffusing the dopant into the second n-type work function layer to form a doped n-type work function layer, wherein a work function of the doped n-type work function layer is different than a work function of the first n-type work function.

9. The method for forming the semiconductor structure as claimed in claim 8, further comprising:
forming a dummy gate structure over the first active region and the second active region;
removing the dummy gate structure to form a gate trench; and
forming a metal fill layer over and in direct contact with the first protection layer and the first p-type work function layer and overfilling the gate trench.

10. The method for forming the semiconductor structure as claimed in claim 9, wherein a third portion of the semiconductor material vertically extends between a sidewall of the metal fill layer and a sidewall of the first p-type work function layer.

11. A method for forming a semiconductor structure, comprising:
forming a first active region and a second active region over a substrate;
forming a dummy gate structure across the first active region and the second active region;
removing the dummy gate structure to form a trench;
forming a first work function layer on the first active region in the trench;
forming a second work function layer on the second active region in the trench;
forming a protection layer on the first work function layer in the trench while exposing the second work function layer; and
forming a metal fill layer on the protection layer and the second work function layer to overfill the trench, wherein a dopant diffuses through the metal fill layer and into the second work function layer during formation of the metal fill layer.

12. The method for forming the semiconductor structure as claimed in claim 11, wherein the protection layer blocks the dopant from diffusing into the first work function layer.

13. The method for forming the semiconductor structure as claimed in claim 11, wherein the first work function layer and the second work function layer are made of a same metal material, and after the dopant diffuses into the second work function layer, a work function of the second work function layer is greater than a work function of the first work function layer.

14. The method for forming the semiconductor structure as claimed in claim 11, further comprising:
forming a stack in which first semiconductor layers and second semiconductor layers are alternately stacked;
patterning the stack into the first active region and the second active region; and
removing the first semiconductor layers of the first active region and the first semiconductor layers of the second active region to form first gaps and second gaps, respectively, wherein the first work function layer and the protection layer fill the first gaps, and the second work function layer fills the second gaps.

15. The method for forming the semiconductor structure as claimed in claim 14, wherein the first gaps are substantially free of the metal fill layer.

16. A semiconductor structure, comprising:
a first n-type transistor comprising a first active region extending in a first direction, a first gate dielectric layer over the first active region, and a first n-type work function layer over the first gate dielectric layer, a first protection layer over the first n-type work function layer, and a first metal fill layer over the first protection layer; and
a first p-type transistor adjacent to the first n-type transistor, the first p-type transistor comprising a second active region extending in the first direction, a second gate dielectric layer over the second active region, a first p-type work function layer over the first gate dielectric layer, and a second metal fill layer over the first p-type work function layer, wherein the first p-type work function layer is doped with oxygen, fluorine, or nitrogen.

17. The semiconductor structure as claimed in claim 16, further comprising:
a second p-type transistor adjacent to the first p-type transistor, comprising a third active region, a third gate dielectric layer over the third active region, a second p-type work function layer over the third gate dielectric layer, a second protection layer over the second p-type work function layer, and a third metal fill layer over the second protection layer,
wherein the first p-type transistor has a first threshold voltage Vp1, the second p-type transistor has a second threshold voltage Vp2, and Vp2<Vp1<0.

18. The semiconductor structure as claimed in claim 17, wherein the first p-type work function layer and the second p-type work function layer are a continuous metal layer, and a dopant concentration of the first p-type work function layer is greater than a dopant concentration of the second p-type work function layer.

19. The semiconductor structure as claimed in claim 16, wherein in a plan view, the first metal fill layer has a first dimension in the first direction, and the second metal fill layer has a second dimension in the first direction, and the first dimension is less than the second dimension.

20. The semiconductor structure as claimed in claim 16, further comprising:
a second n-type transistor adjacent to the first n-type transistor, comprising a third active region, a third gate dielectric layer over the third active region, a second n-type work function layer over the third gate dielectric layer, and a third metal fill layer over the second n-type work function layer, wherein the second n-type work function layer is doped with oxygen, fluorine, or nitrogen,
wherein the second n-type transistor has a first threshold voltage Vn1, the first n-type transistor has a second threshold voltage Vn2, and 0<Vn2<Vn1.
